(19) United States
(12) Patent Application Publication
(10) Pub. No.: US 2026/0050704 A1
(43) Pub. Date: Feb. 19, 2026

(54) AI-BASED EMBROIDERY DESIGN AND MANUFACTURING SYSTEM

(71) Applicant: Zazzle Inc., Menlo Park, CA (US)

(72) Inventors: Richard Peter HOTTELET, Oakland, CA (US); Sharon Derie LIN, Cupertino, CA (US); Leslie Young HARVILL, Olympia, WA (US); Matthew DIFONZO, Belmont, CA (US)

(21) Appl. No.: 18/809,100

(22) Filed: Aug. 19, 2024

(51) Int. Cl. G06F 30/17

(52) U.S. Cl. CPC G06F 30/17

(57) ABSTRACT

In an embodiment, an apparatus for generating embroidery designs comprises: a design generator configured to receive input data including at least one of a text prompt, a reference image, or a combination thereof, and to generate an embroidery-friendly design image; a global decisions module configured to receive the embroidery-friendly design image and metadata, and to generate one or more high-level embroidery plans; a local decisions module configured to receive the one or more high-level embroidery plans and to generate detailed stitch instructions for each Manufacturable Component and layer, including stitch directions, stitch density, and modifications to entry and exit points; a visualizer configured to render multiple variations of the detailed stitch instructions and embroidery designs for review; a reranker configured to score and filter the variations of the detailed stitch instructions; a trainer configured to collect inputs, outputs, and feedbacks to improve the modules.

### TECHNICAL FILED

One technical field of the present disclosure is designing, generating, implementing, and using unique containers for creating and customizing products. Another technical field is computer-implemented techniques for defining, capturing, assembling, and displaying customized content using unique containers. Another technical field uses unique containers to generate manufacturing instructions for customized products.

### BACKGROUND

Embroidery digitization traditionally requires significant manual effort and expertise. The process involves converting a design into a format that machines can interpret, ensuring the final product is both aesthetically pleasing and physically robust. This task demands a deep understanding of various factors, including the type of fabric, the design's complexity, and the desired visual outcome.

Existing systems often fall short in automating this process effectively. They may lack the ability to adapt designs to different contexts, such as varying fabric types or sizes, and often require extensive human intervention to correct errors and optimize the final output.

These limitations highlight the need for a more advanced system that can learn from human feedback and improve over time, reducing the reliance on manual digitization and enhancing the overall efficiency and quality of production.

### SUMMARY

According to one aspect of the present approach, a computer-implemented method for generating embroidery stitch instructions comprises receiving, by a preprocessor module, an input prompt comprising at least one of a text prompt, an image, or a selection input. The method also comprises generating, by the preprocessor module, an embroidery-friendly design based on the input prompt. The embroidery-friendly design comprises quantized colors, cohesive regions on separate layers (also referred to as Visual Components, which contain Manufacturable Components), and additional metadata.

A Cohesive Region, or a Visual Component, is a set of cohesive regions within an embroidery-friendly design are regions that have linear or curvilinear edges that define a closed shape. Such regions may share linear or curvilinear edges. The area within each region may be described by a single color of a limited set of colors (a palette) or by a gradient of two such colors. Additionally, each region may have a textural quality, which is possible to emulate with an embroidery manufacturing system. Each of the cohesive regions may be represented in overlap or rendering order, so that one has precedence over another. This ordering may be called Layering.

The method also comprises receiving, by a Global Decisions Module, the embroidery-friendly design and context information. The context information includes at least one of the size of the final embroidery, the substrate type, the product type, the design title and tags, the manufacturer, and the Digitizer. The method also comprises generating, by the Global Decisions Module, high-level embroidery plans, including the Manufacturable Components, order of the Manufacturable Components, the Fill Type, the entry and exit points for each Manufacturable Component, and the number of Stitch Layers; refining, by a Local Decisions Module (LDM), the high-level embroidery plans into detailed stitch instructions, including stitch directions, stitch density, and modifications to entry and exit points for each Manufacturable Component and Stitch Layer; rendering, by a visualizer module, the embroidery design and high-level decisions as a diagram for human review; scoring and reordering, by a reranker module, variations of the embroidery stitch plans based on predefined criteria; selecting, by a human Verifier, a preferred embroidery rendering from the sorted list of variations; reviewing and correcting, by a Digitizer, the selected embroidery plan; manufacturing, by an embroidery machine, the physical embroidery based on the corrected stitch plan; collecting, by a trainer module, inputs, outputs, and human feedback from the Verifier, Digitizer, and manufacturing Inspector; updating, by the trainer module, the preprocessor module, Global Decisions Module, and Local Decisions Module based on the collected feedback to improve future performance.

According to another aspect, the system wherein the design generator is configured to process multiple types of inputs simultaneously, including text prompts and reference images.

According to yet another aspect, the system wherein the design generator refines the input based on Verifier feedback, allowing iterative improvements to the design.

According to one aspect of the present approach, the system wherein the Global Decisions Module uses discrete sequence prediction models to generate high-level embroidery plans.

According to another aspect, the system wherein the Global Decisions Module incorporates context-specific information such as substrate type, product type, and design size to tailor the embroidery plans.

According to yet another aspect, the system wherein the Local Decisions Module uses hierarchical diffusion models to generate detailed stitch instructions layer-by-layer.

According to one aspect of the present approach, the system wherein the Local Decisions Module refines entry and exit points, stitch directions, and stitch density based on the high-level plans from the Global Decisions Module.

According to another aspect, the system wherein the visualizer uses advanced rendering techniques to create realistic simulations of the final embroidery.

According to yet another aspect, the system wherein the visualizer ensures that the rendered design matches the final embroidery by simulating the physical properties of the stitches and substrate.

According to one aspect of the present approach, a non-transitory computer-readable storage media storing one or more computer instructions which, when executed by one or more computer processors, cause the one or more computer processors to perform: receiving, by a preprocessor module, an input prompt comprising at least one of a text prompt, an image, or a selection input; generating, by the preprocessor module, an embroidery-friendly design based on the input prompt, wherein the embroidery-friendly design comprises quantized colors, cohesive regions on separate layers, and additional metadata; receiving, by a Global Decisions Module, the embroidery-friendly design and context information, wherein the context information includes at least one of the size of the final embroidery, the substrate type, the product type, the design title and tags, the manufacturer, and the Digitizer; generating, by the Global Decisions Module, high-level embroidery plans, including the order of Manufacturable Components to embroider, the Fill Type, the entry and exit points for each Manufacturable Component, and the number of Stitch Layers; refining, by a Local Decisions Module, the high-level embroidery plans into detailed stitch instructions, including stitch directions, stitch density, and modifications to entry and exit points for each Manufacturable Component and Stitch Layer; rendering, by a visualizer module, the embroidery design and high-level decisions as a diagram for human review; scoring and reordering, by a reranker module, variations of the embroidery stitch plans based on predefined criteria; selecting, by a human Verifier, a preferred embroidery rendering from the sorted list of variations; reviewing and correcting, by a Digitizer, the selected embroidery plan; manufacturing, by an embroidery machine, the physical embroidery based on the corrected stitch plan; collecting, by a trainer module, inputs, outputs, and human feedback from the Verifier, Digitizer, and manufacturing Inspector; updating, by the trainer module, the preprocessor module, Global Decisions Module, and Local Decisions Module based on the collected feedback to improve future performance.

According to another aspect, an apparatus for generating embroidery designs comprises a design generator configured to receive input data including at least one of a text prompt, a reference image, or a combination thereof, and to generate an embroidery-friendly design image with quantized colors, cohesive regions on separate layers, and additional metadata; a Global Decisions Module configured to receive the embroidery-friendly design image and metadata, and to generate high-level embroidery plans including the order of Manufacturable Components, number of stitch layers, Fill Type, and entry and exit points for each Manufacturable Component; a Local Decisions Module configured to receive the high-level embroidery plans and to generate detailed stitch instructions for each Manufacturable Component and Stitch Layer, including stitch directions, stitch density, and modifications to entry and exit points; a visualizer configured to render multiple variations of the stitch instructions and embroidery designs for review; a reranker configured to score and filter the variations based on predefined criteria; a trainer configured to collect inputs, outputs, and human feedback from various stages, and to fine-tune the design generator, Global Decisions Module, and Local Decisions Module based on the collected data.

According to yet another aspect, the system wherein the design generator is configured to process multiple types of inputs simultaneously, including text prompts and reference images.

According to one aspect of the present approach, the system wherein the design generator refines the input based on Verifier feedback, allowing iterative improvements to the design.

According to another aspect, the system wherein the Global Decisions Module uses discrete sequence prediction models to generate high-level embroidery plans.

According to yet another aspect, the system wherein the Global Decisions Module incorporates context-specific information such as substrate type, product type, and design size to tailor the embroidery plans.

According to one aspect of the present approach, the system wherein the Local Decisions Module uses hierarchical diffusion models to generate detailed stitch instructions layer-by-layer.

According to another aspect, the system wherein the Local Decisions Module refines entry and exit points, stitch directions, and stitch density based on the high-level plans from the Global Decisions Module.

According to yet another aspect, the system wherein the visualizer uses advanced rendering techniques to create realistic simulations of the final embroidery.

According to one aspect of the present approach, the system wherein the visualizer ensures that the rendered design matches the final embroidery by simulating the physical properties of the stitches and substrate.

### BRIEF DESCRIPTION OF THE DRAWINGS

The patent or application file contains at least one drawing executed in color. Copies of this patent or patent application publication with color drawing will be provided by the Office upon request and payment of the necessary fee.

So that the manner in which the above-recited features of the present disclosure can be understood in detail, a more particular description of the disclosure, briefly summarized above, may be had by reference to aspects, some of which are illustrated in the appended drawings. It is to be noted, however, that the appended drawings illustrate only typical aspects of this present disclosure and are therefore not to be considered limiting of its scope, for the present disclosure may admit to other equally effective aspects.

FIG. 1 is a schematic block diagram illustrating a workflow and modules of an AI embroidery system.

FIG. 2 depicts a high-level diagram illustrating a process for generating global decisions in an AI embroidery system.

FIG. 3A depicts a high-level diagram of the decision-making process for generating stitch instructions in an AI embroidery system.

FIG. 3B depicts a high-level diagram of color quantization and clustering.

FIG. 4 is an example of stitch regions and Z-ordering.

FIG. 5 is an example of stitch regions and Z-ordering.

FIG. 6 is a block diagram showing an example computer environment.

FIG. 7 is a block diagram showing an example of collaboration platform.

FIG. 8A is a flow chart depicting an example process for generating embroidery stitch instructions using an AI-based embroidery system.

FIG. 8B is a flow chart depicting an example process for generating embroidery stitch instructions using an AI-based embroidery system.

FIG. 9A is a flow chart depicting an example process for generating and refining embroidery designs using an AI-based embroidery system.

FIG. 9B is a flow chart depicting an example process for generating and refining embroidery designs using an AI-based embroidery system.

FIG. 10 is a flow chart depicting an example process for color quantization and clustering.

FIG. 11 is a block diagram that illustrates a computer system with which the techniques herein may be implemented.

All the drawings, descriptions and claims in this disclosure are intended to present, disclose, and claim a technical system and technical methods in which specially programmed computers, using a special-purpose distributed computer system design, execute functions that have not been available before to provide a practical application of computing technology to the problem of machine learning model development, validation, and deployment. In this manner, the disclosure presents a technical solution to a technical problem, and any interpretation of the disclosure or claims to cover any judicial exception to patent eligibility, such as an abstract idea, mental process, method of organizing human activity or mathematical algorithm, has no support in this disclosure and is erroneous.

### DESCRIPTION OF EXAMPLE EMBODIMENTS

In the following description, for the purposes of explanation, numerous specific details are set forth in order to provide a thorough understanding of the present approach. It will be apparent, however, that the present approach may be practiced without these specific details. In other instances, well-known structures and devices are shown in block diagram form in order to avoid unnecessarily obscuring the present approach.

Embodiments are described herein according to the following outline:
1.0. GENERAL OVERVIEW
   1.1. TECHNICAL PROBLEM-TECHNICAL SOLUTION
   1.2. TECHNICAL EFFECTS
   1.3. APPROACH SUMMARY
2.0. EXAMPLE EMBODIMENTS
   2.1. EXAMPLE EMBODIMENTS OF A PROCESS
   2.2. EXAMPLE EMBODIMENTS OF AN APPARATUS
3.0. EXAMPLE EMBROIDERY SYSTEM
   3.1. FIRST EXAMPLE-A NEURAL NETWORK PLUS GRAPH OPTIMIZATION APPROACH
   3.2. SECOND EXAMPLE-A FULL NEURAL NETWORK APPROACH
      3.2.1. FIRST VARIATION
      3.2.2. SECOND VARIATION
4.0. EXAMPLE HIGH-LEVEL DIAGRAM
5.0. EXAMPLE HIGH-LEVEL DIAGRAM FOR GENERATING AND REFINING EMBROIDERY DESIGN
   5.1. DECISION-MAKING PROCESS
6.0. COLOR QUANTIZATION AND CLUSTERING
7.0. EMBROIDERY EXAMPLE
8.0. EXAMPLE COMPUTER ENVIRONMENTS
   8.1. USER DEVICES
   8.2. CLIENT APPLICATIONS
   8.3. FRONT AND END SERVERS
   8.4. CORE SERVICES
9.0. EXAMPLE MANUFACTURING SYSTEM
10.0. EXAMPLE PRODUCT COLLABORATION PLATFORM
11.0. PROCESS FOR GENERATING EMBROIDERY STITCH INSTRUCTIONS USING AI-BASED EMBRODIERY SYSTEM
12.0. PROCESS FOR REFINING EMBROIDERY DESIGNS USING AN AI-DRIVED EMBROIDERY SYSTEM
13.0. COLOR QUANTIZATION AND CLUSTERING
14.0. IMPLEMENTATIONS MECHANISMS

### 1.0. GENERAL OVERVIEW

The following terms are used throughout the description:

Border Type—Can be any of the following: Running stitch, bean stitch, backstitch, chain stitch, blanket stitch, satin stitch, e-stitch, motif stitch, scallop stitch, picot edge, feather stitch, herringbone stitch, couching stitch, double run stitch, triple run stitch, programmed run stitch, cross-stitch border, contour stitch, candlewick stitch.

COGS—Costs like stitching/manufacturing time and thread usage or other inventory expenses.

Context—Information related to the embroidery substrate, product type, production environment, audience, etc., that may affect embroidery implementation decisions. Examples include:
Substrate
Product Type/Availability
Design Area Dimensions and/or Constraints
Available processes/colors (e.g., fill types)
Embroidery Preferences
Machine Type/Manufacturer (e.g., Melco, Brother, Bolton)
Manufacturing Environment.

Denoising sub-module—a neural network module designed to iteratively remove noise from data. It takes a noisy input and a noise level as parameters, and outputs a less noisy version of the input. Each iteration is a time step. This submodule is crucial in the reverse process of a diffusion model within this workflow, where it generates Refined Decisions, guided by the Context Encoder.

Design Requirements-Elements or other data that could be inform the output, including a reference design, a text prompt, a multimodal input prompt, or other specific Contexts from the Verifier or known/pre-stored Contexts from another source.

Embroidery-friendly design—The design we want to embroider. It represents the design intent and exists outside the context of a specific embroidery instance. Examples may include:
A limited set of colors
An ordered list of Visual Components
Metadata for each Visual Component
Optional reference stitch plans (if the design has been embroidered before, and the goal is to adapt the plan to a different context, then an optional reference stitch plan may be included).
   The embroidery—friendly design can be rendered as a flattened image (e.g., an image of a lizard we want to embroider). The same embroidery-friendly design can be embroidered in multiple different contexts (e.g., a shirt, napkin, and tablecloth).

Fill Type—Defines the treatment of a contiguous area containing stitched thread, a complex pattern (e.g., a programmed fill to be integrated by the LDM), Motif fill (e.g., a tiled pattern of stars), Programmed fill stitch (e.g., a more complex fill pattern like woodgrain, typically sourced from a library), Applique (e.g., for adding additional material layers like denim), Cutwork (for areas that need to be cut or removed, for example, on a doily or lace design, buttonholes, or contour cut patches), 3D puff (e.g., for products like hats with a raised/3D logo), Sequins, Fur stitch, Chenille, Rhinestones, Fringe, Needle felting, Couching, or 2D printed areas (e.g., DTG or giclee print+embroidery border).

Fill Stitch Type—a fill comprised of embroidery thread of a specific color (or specific effect like metallic/glow in the dark): Satin stitch (i.e. the lizard design), Tatami stitch (for visual effect or to minimize back float over large fill areas), Running Stitch (e.g., for outlining), Zig-zag stitch (e.g., for edging or decorative areas), Stemstich (e.g., for floral designs), Contour stitch (e.g., for visual effect), Cross-stitch fill (e.g., mimics handmade cross-stitch), Stipple stitch, Ripple stitch (e.g., to simulate water), Wave fill (also to simulate water), Radial fill, Spiral fill, Embossed fill (with thread, without puff foam), Moss stitch, Bobbin work.

Functional Stitch Type—Can be any of the following: placement stitches, tie-off stitches, tack down stitches, basting stitches, registration marks, trim lines, knockdown stitches, quilting stitches, cutwork guide stitches, freestanding guide stitches, stop stitches, trimming stitches, underlay stitching (for creating an Underlay Pattern, defined below).

Global Decisions Module (GDM)—Makes high-level decisions for the embroidery plan and overall semantic decisions regarding the design. Serves as a coordinator for decision-making. Receives the Embroidery-friendly Design and the Context from the Preprocessor. Outputs the Manufacturable Components, the order of the Manufacturable Components in the plan, number of Stitch Layers, Fill Type, and entry/exit points per Manufacturable Component. May also output the rough coverage area of each Stitch Layer.

Image—A 2D arrangement of colored pixels (e.g., png, jpg, bmp).

Image/Text/Selector (ITS)—provides the initial input data, including the reference design and text prompt, and context from the Context Selector, to the Preprocessor.

Context Selector is a sub-unit (or sub process) of the ITS-provides additional information to the GDM to aid in generating high-level embroidery plans.

Known Verifier Preferences—Limitations or other information that would inform the choices made by the Preprocessor and Global Decisions Module (e.g., “this Verifier always wants ripple fill used to depict water”, or “this Verifier only wants designs for polo shirts with a 2×2 design area”).

Local Decisions Module (LDM)—Makes specific decisions regarding execution and machine behavior. Outputs the actual stitch instructions for each Stitch Layer and their order within a Manufacturable Component.

Manufacturable Component-Subsets of Visual Components that are identified within the embroidery plan. Manufacturing Components contain Layers. Manufacturable Components have the following characteristics:
Are manufacturable, meaning that they are able to be expressed in machine instructions.
They are typically created using a single thread color, but may incorporate multiple thread types or colors (e.g., to achieve a gradient effect).
They maintain perceptual unity, either semantically or artistically.
They are broken down into one or more Stitch Layers, which may potentially overlap.
They are determined by the Global Decisions Module (GDM) as part of the high-level embroidery plans.
They may be further refined or adjusted by the Local Decisions Module (LDM) during the detailed stitch instruction generation process.
We will use per-Manufacturable-Component to mean “as pertaining to” Manufacturable Component

Preprocessor—Collects design requirements and rules out all unusable options, retaining only usable options. Works with the Verifier to create an Embroidery-friendly Design and an embroidery Context. Defines the Visual Components of the Embroidery-friendly Design, but not the Manufacturable Components.

Ranker—The Ranker scores and reorders variations of embroidery stitch plans based on predefined criteria (e.g., COGs, physical robustness, fidelity to intent, etc.).

Stitch Layer-A continuous stitch path. The path may cross over itself. The layer could include Functional Stitch Types (e.g., including travel stitches and tie-off stitches), Underlay Pattern, Fill Stitch Type, and Border Type. We will use per-Stitchable-Layer to mean “as pertaining to” Stitch Layers

Verifier—The entity (human or machine agent) that:
Generates design intent and embroidery Context
Communicates the intent through multiple modalities (e.g., images, text, selection, etc.)
Works with the Preprocessor to refine an Embroidery-friendly Design and an embroidery Context.

Underlay Pattern—Can be any of the following: Edge run, center run, zig-zag, double zig-zag, lattice, contour, full lattice, parallel, perpendicular, cross-hatch, random, tatami, split, bordering, web, mesh, spiral, contour parallel, blanket.

Visual Component—A contiguous area in the Embroidery-friendly design that:
Typically comprises one quantized color but may incorporate multiple quantized colors (e.g., in the case of a gradient).
It may not be entirely visible in the “flattened” image of the Embroidery-friendly design. For example, a yellow smiley face may have a solid yellow circle as one Visual Component, even if the eyes and mouth obscure parts of that circle. This allows for Visual Components to have overlapping regions within the Embroidery-friendly design.
Should be perceived as a unit (either semantically and/or artistically). Even if two areas in the design are the same color and are contiguous, they may represent different objects, and/or the Verifier may intend them to be perceived as distinct entities. In such cases, they would be classified as separate Visual Components. For example, if a red dog silhouette touches a red person silhouette, it may be appropriate to define them as two distinct Visual Components rather than merging them into one. However, if the artistic intent is to maintain ambiguity regarding where, e.g., the dog ends and the person begins, they could be defined as a single Visual Component.
Is subsequently decomposed into one or more Manufacturable Components.

Z-order—Z ordering is specifically the stacking order of Stitch Layers, Manufacturable Components, and Visual Components from bottom (first Stitch Layer) to top (last Stitch Layer).

### 1.1. Technical Problem—Technical Solution

Embroidery digitization and the process of converting a design into a format that an embroidery machine can interpret usually presents significant challenges. This process requires a high level of expertise and manual effort to ensure that the final embroidered product is both aesthetically pleasing and physically robust. The digitization process involves multiple steps, including design ideation, stitch planning, and the generation of machine-readable instructions. Each step demands careful consideration of various factors such as the type of fabric, the complexity of the design, and the desired visual effect.

Current solutions for embroidery digitization often rely heavily on human expertise and manual intervention. Traditional methods involve skilled Digitizers who manually convert designs into stitch files, a process that is time-consuming and prone to human error. These methods lack the ability to efficiently handle complex designs or adapt to different contexts, such as varying fabric types or product sizes. Additionally, existing systems do not effectively incorporate feedback from multiple stages of the embroidery process, leading to inconsistencies and suboptimal results.

The disclosed system addresses these challenges by introducing an AI-driven approach to embroidery digitization. This system facilitates the ideation and production of embroidered designs tailored to Verifier preferences while ensuring physical robustness. By leveraging machine learning models and continuous human feedback, the system learns from existing embroidery stitch files and improves over time. The system comprises several modules, including a design generator, Global Decisions Module, Local Decisions Module, visualizer, reranker, and trainer, each playing a role in the digitization process.

The design generator works with the Verifier to ideate and refine the embroidery concept, producing an embroidery-friendly design image. The Global Decisions Module then creates high-level embroidery plans, determining the order of Manufacturable Components, Fill Types, and entry and exit points. The Local Decisions Module refines these plans into detailed stitch instructions, ensuring precision and consistency. The visualizer renders the embroidery design for human review, while the reranker scores and filters variations based on predefined criteria. The trainer module collects inputs, outputs, and feedback to continuously improve the system's performance.

### 1.2. Technical Effects

In some implementations, the preprocessor module's ability to receive various types of input prompts, such as text, images, or selection inputs, allows for a flexible and user-friendly interface. This flexibility ensures that users with different levels of expertise and different types of design ideas can effectively interact with the system, making the design process more accessible and efficient.

By generating an embroidery-friendly design with quantized colors, cohesive regions on separate layers, and additional metadata, the preprocessor module simplifies the complex task of converting a raw design into a format suitable for embroidery. This preprocessing step reduces the manual effort required and ensures that the design is optimized for the subsequent stages of the embroidery process.

The Global Decisions Module's use of context information, such as the size of the final embroidery, substrate type, product type, design title and tags, manufacturer, and Digitizer, allows for the generation of high-level embroidery plans that are tailored to specific requirements. This context-aware approach ensures that the embroidery plans are not only aesthetically pleasing but also physically robust, taking into account the unique characteristics of each project.

The generation of high-level embroidery plans by the Global Decisions Module, including the order of Manufacturable Components, Fill Type, entry and exit points, and the number of stitch layers, provides a structured and systematic approach to embroidery planning. This reduces the likelihood of errors and inconsistencies, ensuring a higher-quality final product.

The Local Decisions Module's refinement of high-level embroidery plans into detailed stitch instructions, including stitch directions, stitch density, and modifications to entry and exit points, ensures precision and accuracy in the final embroidery. This detailed level of planning helps in achieving a high-quality finish and reduces the need for manual corrections.

The visualizer module's capability to render the embroidery design and high-level decisions as a diagram for human review provides a clear and understandable representation of the design. This visualization aids in identifying potential issues early in the process and allows for informed decision-making by the user.

The reranker module's function of scoring and reordering variations of the embroidery stitch plans based on predefined criteria ensures that only the most promising designs are presented to the user. This filtering process saves time and effort by eliminating suboptimal designs and focusing on the best options.

The involvement of a human Verifier in selecting a preferred embroidery rendering from the sorted list of variations ensures that the final design aligns with the Verifier's preferences and expectations. This step adds a layer of personalization and satisfaction to the process.

The review and correction of the selected embroidery plan by a Digitizer ensures that any potential issues are addressed before manufacturing. This human oversight adds an additional layer of quality control, ensuring that the final product meets high standards of both aesthetics and durability.

The manufacturing of the physical embroidery based on the corrected stitch plan by an embroidery machine ensures that the final product is produced accurately and efficiently. This automation reduces the time and effort required for production, increasing overall efficiency.

The collection of inputs, outputs, and human feedback by the trainer module from various stages of the process allows for continuous improvement of the system. By updating the preprocessor module, Global Decisions Module, and Local Decisions Module based on collected feedback, the system becomes more accurate and efficient over time, reducing the reliance on manual intervention and enhancing the overall quality of the embroidery designs.

In some implementations, the preprocessor module's ability to receive various types of input prompts, such as text, images, or selection inputs, allows for a flexible and user-friendly interface. This flexibility ensures that users with different levels of expertise and different types of design ideas can effectively interact with the system, making the design process more accessible and efficient.

By generating an embroidery-friendly design with quantized colors, cohesive regions on separate layers, and additional metadata, the preprocessor module simplifies the complex task of converting a raw design into a format suitable for embroidery. This preprocessing step reduces the manual effort required and ensures that the design is optimized for the subsequent stages of the embroidery process.

The Global Decisions Module's use of context information, such as the size of the final embroidery, substrate type, product type, design title and tags, manufacturer, and Digitizer, allows for the generation of high-level embroidery plans that are tailored to specific requirements. This context-aware approach ensures that the embroidery plans are not only aesthetically pleasing but also physically robust, taking into account the unique characteristics of each project.

The generation of high-level embroidery plans by the Global Decisions Module, including the order of Manufacturable Components, Fill Type, entry and exit points, and the number of stitch layers, provides a structured and systematic approach to embroidery planning. This reduces the likelihood of errors and inconsistencies, ensuring a higher quality final product.

The Local Decisions Module's refinement of high-level embroidery plans into detailed stitch instructions, including stitch directions, stitch density, and modifications to entry and exit points, ensures precision and accuracy in the final embroidery. This detailed level of planning helps in achieving a high-quality finish and reduces the need for manual corrections.

The visualizer module's capability to render the embroidery design and high-level decisions as a diagram for human review provides a clear and understandable representation of the design. This visualization aids in identifying potential issues early in the process and allows for informed decision-making by the user.

The reranker module's function of scoring and reordering variations of the embroidery stitch plans based on predefined criteria ensures that only the most promising designs are presented to the user. This filtering process saves time and effort by eliminating suboptimal designs and focusing on the best options.

The involvement of a human Verifier in selecting a preferred embroidery rendering from the sorted list of variations ensures that the final design aligns with the Verifier's preferences and expectations. This step adds a layer of personalization and satisfaction to the process.

The review and correction of the selected embroidery plan by a Digitizer ensures that any potential issues are addressed before manufacturing. This human oversight adds an additional layer of quality control, ensuring that the final product meets high standards of both aesthetics and durability.

The manufacturing of the physical embroidery based on the corrected stitch plan by an embroidery machine ensures that the final product is produced accurately and efficiently. This automation reduces the time and effort required for production, increasing overall efficiency.

The collection of inputs, outputs, and human feedback by the trainer module from various stages of the process allows for continuous improvement of the system. By updating the preprocessor module, Global Decisions Module, and Local Decisions Module based on collected feedback, the system becomes more accurate and efficient over time, reducing the reliance on manual intervention and enhancing the overall quality of the embroidery designs.

### 2.0. EXAMPLE EMBODIMENTS

### 2.1. Example Embodiments of a Process

In some embodiments, an AI embroidery system is designed to handle a wide range of input prompts, including text descriptions, images, and selection inputs. The preprocessor module can process these inputs to generate an embroidery-friendly design by quantizing colors, separating the image into cohesive regions on separate layers, and adding metadata such as predicted semantics of each region. This design is then fed into the Global Decisions Module, which takes into account context information like the size of the final embroidery, the substrate type, the product type, the design title and tags, the manufacturer, and the Digitizer. The Global Decisions Module generates high-level embroidery plans, including the order of Manufacturable Components to embroider, the Fill Type, the entry and exit points for each Manufacturable Component, and the number of Stitch Layers. These high-level plans are further refined by the Local Decisions Module, which provides detailed stitch instructions, including stitch directions, stitch density, and modifications to entry and exit points for each Manufacturable Component and Stitch Layer. The visualizer module then renders the embroidery design and high-level decisions as a diagram for human review, allowing for realistic simulations of the final embroidery. A reranker module scores and reorders variations of the embroidery stitch plans based on predefined criteria, ensuring that only the most promising designs are presented to the human Verifier. The Verifier selects their preferred embroidery rendering from the sorted list of variations, which is then reviewed and corrected by a Digitizer. The corrected stitch plan is used by an embroidery machine to manufacture the physical embroidery. Throughout this process, a trainer module collects inputs, outputs, and human feedback from the Verifier, Digitizer, and manufacturing Inspector, and updates the preprocessor module, Global Decisions Module, and Local Decisions Module based on the collected feedback to improve future performance. This embodiment ensures a robust, artistically pleasing, and contextually appropriate embroidery design process.

### 2.2. Example Embodiments of an Apparatus

In some embodiments, an apparatus for generating embroidery designs includes a design generator that can process various types of input data, such as text prompts, reference images, or a combination of both, to create an embroidery-friendly design image. This design image features quantized colors, cohesive regions on separate layers, and additional metadata to facilitate the embroidery process. The Global Decisions Module then receives this design image and metadata to generate high-level embroidery plans, which include the order of Manufacturable Component, the number of Stitch Layers, the Fill Type, and the entry and exit points for each Manufacturable Component. In another embodiment, the Global Decisions Module can incorporate context-specific information such as the substrate type, product type, and design size to tailor the embroidery plans more precisely. The Local Decisions Module refines these high-level plans into detailed stitch instructions for each Manufacturable Component and Stitch Layer, specifying stitch directions, stitch density and any necessary modifications to entry and exit points. This module may use hierarchical diffusion models to generate these detailed instructions layer-by-layer. The visualizer then renders multiple variations of the stitch instructions and embroidery designs for review, using advanced rendering techniques to create realistic simulations of the final embroidery. In yet another embodiment, the visualizer ensures that the rendered design matches the final embroidery by simulating the physical properties of the stitches and substrate. The reranker scores and filters these variations based on predefined criteria, and the trainer collects inputs, outputs, and human feedback from various stages to fine-tune the design generator, Global Decisions Module, and Local Decisions Module, thereby improving the system's performance over time.

### 3.0. EXAMPLE EMBROIDERY SYSTEM

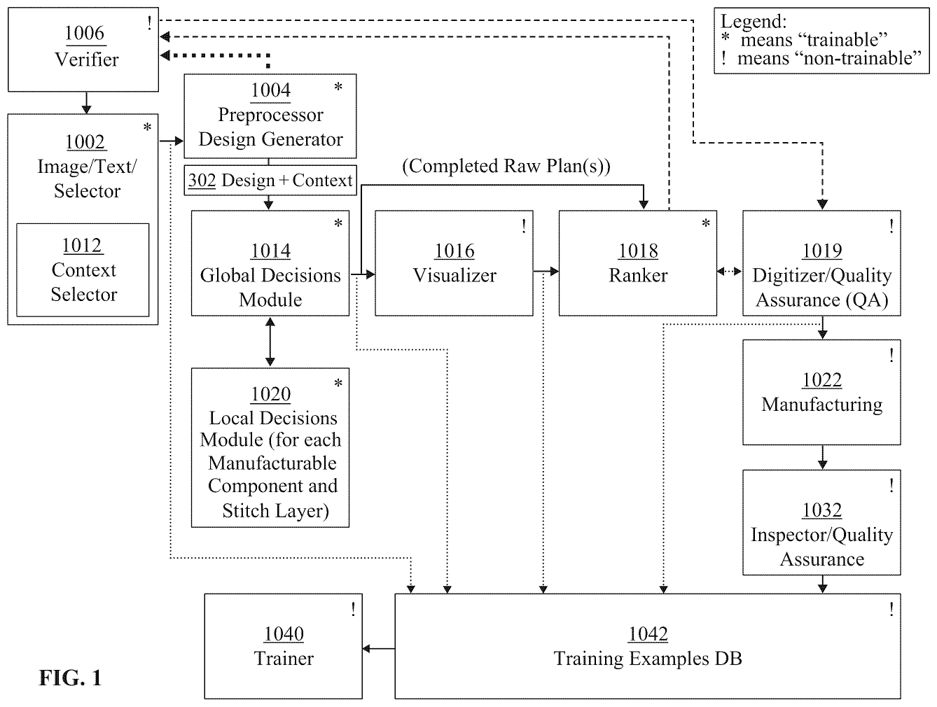

FIG. 1 shows an AI-driven embroidery system comprising a Selector 1002, a Preprocessor 1004, a Verifier 1006, a Context Selector 1012, a Global Decisions Module (GDM) 1014, a Local Decisions Module (LDM) 1020, a Visualizer 1016, a Ranker 1018, a Digitizer 1019, Manufacturing 1022, an Inspector 1032, a Trainer 1040, and a Training Examples DB (TED) 1042. The system facilitates the generation and refinement of embroidery designs through various interconnected modules.

The Verifier provides initial Design Requirements to the Image/Text/Selector (ITS). The ITS queries the Context Selector (internal to the ITS) for any additional details that may be required to move forward, and uses an efficient, internally consistent method of structured data exchange (e.g., an API) to send a complete request to the Preprocessor (where the request contains the Verifier's Design Requirements plus any additional required Contexts).

If a reference design from the Verifier is included in the Design Requirements, the Preprocessor may first extract any relevant metadata (including exif data, tags, etc.) and normalize the reference design input for optimal use by the system. Normalization includes resizing for performance or other system optimization, applying noise reduction, and adjusting hue, saturation, or brightness to improve feature detection. It converts the color space (e.g., to Lab or HSV for greater perceptual uniformity). Image enhancement processes are applied (e.g., a sharpening filter to accentuate borders in a design). The Preprocessor then performs alpha channel handling according to predefined rules (e.g., flattening to white, another color, or preserving transparency).

The Preprocessor employs a color quantization algorithm (such as k-means, octree, or hierarchical clustering) to reduce the color palette. This reduction adheres to machine embroidery constraints, including minimum/maximum available area sizes and maximum color changes. An edge-detection algorithm identifies boundaries between color areas, followed by path simplification if necessary. Connected component analysis then identifies distinct areas of the same color. Semantic segmentation identifies and tags objects or regions that might require different embroidery techniques. The Preprocessor consults with the Verifier if appropriate (e.g., in the case of a Fill Type that would increase COGS past a known or estimated limit). Texture analysis identifies areas that could be improved using special Functional Stitch Types or Fill Styles. Topological and semantic data analysis examines the structure and relationships between different color regions, recommending specific Visual Components. Each contiguous area of a single color or semantic meaning is potentially a Visual Component, though Visual Components identified here may be broken up further by the GDM as Manufacturable Components. Segmentation and analysis occur at multiple scales, providing optimal results for color areas of various sizes and configurations, and the results are merged for a holistic evaluation. Alternatively, image vectorization techniques such as LIVE could convert the limited-color image to a layered SVG vector format.

The Preprocessor uses a multimodal processing system for Design Requirements with inputs beyond a design reference (e.g., a text prompt input+a design reference image). This system interprets inputs in the context of embroidery limitations and capabilities, potentially using a fine-tuned latent diffusion model to generate embroidery-friendly design output. This output is pre-normalized. Colors in the output can represent either keys for thread colors or keys to identify areas that could be treated with a specific Fill Type. The Preprocessor interacts with the ITS via an efficient, internally consistent method of structured data exchange (e.g., an API). It responds to the ITS with a processed embroidery-friendly design. The ITS collects any additional feedback from the Verifier and moves forward in the process when appropriate. The Verifier provides initial Design Requirements to the ITS. The ITS queries the Context Selector (internal to the ITS) for any additional details that may be required to move forward, and uses an efficient, internally consistent method of structured data exchange (e.g., an API) to send a complete request to the Preprocessor (where the request contains the Verifier's Design Requirements plus any additional required Contexts).

The Verifier provides the initial design requirements and feedback during the design process. The Verifier interacts with the Preprocessor, Visualizer, and Ranker to refine the embroidery design. The Verifier's inputs are stored in the system's database for future reference and learning. The Verifier can use any multimodal input to refine the output generated by the Preprocessor.

The Global Decisions Module (GDM) receives the embroidery-friendly design and Context information from the Preprocessor. The system uses an efficient, internally consistent method of structured data exchange (e.g., an API) to send a request to the embroidery planning service, which starts with the GDM. This request contains structured data representing the image and context information. The GDM generates high-level embroidery plans, including refining the Visual Components of the Embroidery-friendly design into Manufacturable Components, determining the order of Manufacturable Components, the number of stitch layers, the Fill Type, and the entry and exit points for each Manufacturable Component using machine learning models trained on previous embroidery designs—for example, a conditional diffusion model or patch-based model. To refine Visual Components into Manufacturable Components, a segmentation algorithm is used to break a Visual Component into one or more Manufacturable Components. These Manufacturable Components are intended to be completed atomically in the embroidery plan. The segmentation algorithm could be neural network-based (e.g., the Segment Anything Model trained on example Visual Component breakdowns into Manufacturable Components), generating multiple proposals for segmentations. For each area identified as a potential Manufacturable Component, pre-trained neural networks may be employed to predict COGS and other known limitations (e.g., estimating costs like stitching/manufacturing time and thread usage) to score the proposals and determine the best one.

To determine the execution order of the Manufacturable Components and other high-level decisions, there are a few possible implementations.

### 3.1. First Example—a Neural Network Plus Graph Optimization Approach

In this example, a neural network model predicts the Fill Type and stitch properties for each Manufacturable Component based on its visual appearance, metadata, and the embroidery Context. The GDM then uses a directional spatial relationship graph (DSRG), which is populated using data from the LDM to analyze the relationships between Stitch Layers (e.g., underlay stitch to underlay stitch, underlay to fill, fill to fill, or Special Fill Type interactions). Each vertex in the graph represents a specific layer, containing information like layer type/Fill Type, Manufacturable Component membership, thread color, x/y positioning, entry/exit, and stitch properties. Each arc in the graph represents a potential transition between two Stitch Layers, containing a weight (the “cost” of the transition) and a direction. Intra-Manufacturable-Component arcs connect layers within the same Manufacturable Component, recognizing constraints like an underlay being stitched before a fill. They may imply machine behavior like a color change for Manufacturable Components (e.g., for a Gradient effect, different color Stitch Layers would be combined to produce the intended result) Inter-Manufacturable-Component arcs connect Stitch Layers to temporally neighboring Manufacturable Component exit/entry points in the GDM predicted sequence and may also imply machine behavior like a color change. The graph could have multiple arcs between vertices representing alternate transition strategies. Not every Stitch Layer can necessarily transition directly to every other Stitch Layer (due to possible constraints like overlap and visual effect). The system uses topological sorting (e.g., using DFS) on the DSRG to determine a correct stitching order, taking into account layer dependencies and design requirements. The system traverses the graph using a traveling salesman, constrained path optimization algorithm (e.g., Constraint Programming+Large Neighborhood Search, Mixed Integer Programming, Genetic Algorithm) to visit all vertices while minimizing the total weight of traversed arcs.

Segmentation and optimization algorithms then estimate the “best” division and an ideal number of Stitch Layers within the Manufacturable Component to balance fidelity in comparison with the original design against feasibility (e.g., machine performance considerations, physical limitations or requirements, and COGS). This information is then passed to the Local Decisions Module for final decision-making in these areas.

### 3.2. Second Example—a Full Neural Network Approach

In this example, the GDM uses a sequence prediction model, such as a discrete diffusion model, to output a sequence of global decisions for each Manufacturable Component.

The GDM interacts with the Preprocessor and Local Decisions Module (LDM) to coordinate the design process through an internally consistent method of structured data exchange (e.g., an API). The GDM may use a discrete sequence prediction model to output a sequence of global decisions for each Manufacturable Component. For example, this may be a discrete diffusion model that has a context encoder that will take the input layered image, metadata, and embroidery context and output one or more vectors of numbers representing the embroidery intent. This context vector will be used to condition the discrete diffusion model during inference. The discrete diffusion model outputs a sequence of tokens that represent high-level decisions, like the order of a Manufacturable Component in the embroidery sequence, the number of embroidery layers needed to cover the Manufacturable Component, rough entry and exit points, and the Fill Type. The discrete diffusion model has been pre-trained on a large dataset of embroidery design plans with their associated input and Context. The GDM ensures the physical robustness and artistic appearance of the entire digitization. This could be built-in to the model through training on the embroidery examples, where the model learns the best practices implicitly encoded in the examples. Adversarial training may also be used to incorporate more explicit examples of good versus bad embroidery plans in the context of physical robustness and/or artistic appearance. Additional sub-models/branches in the diffusion model can be used to predict visual outputs/appearance, which is used as part of training to teach the diffusion model how to interpret its decisions visually (e.g., the effect of Manufacturable Component ordering decisions on the embroidery appearance).

The Local Decisions Module (LDM) refines the high-level embroidery plans on a per-Manufacturable-Component and per-Stitchable-Layer basis. The Local Decisions Module determines the final content for the layers within each Manufacturable Component and determines the appropriate Stitch Layers to achieve the plan as enumerated by the GDM.

### 3.2.1. First Variation

In one implementation, based on Manufacturable Component specifics (size/shape/substrate/metadata), Context, and GDM decisions, the LDM system receives a plan from the GDM and creates specific stitch instructions based on the plan. If required, each Manufacturable Component determines an appropriate underlay pattern stitch type and generates an Underlay Pattern composed of one or more Stitch Layers optimized for entry/exit against nearby Manufacturable Components. If a stitched fill is required, it generates an optimized fill pattern using an appropriate line-sweeping algorithm (e.g., linear, contour-parallel, spiral) to determine the optimal stitch direction. It then composes one or more Stitch Layers, selecting an optimal scheme for executing the chosen fill pattern based on Manufacturable Component size, shape, and context, including overall design context.

For example, a satin stitch may be appropriate for a smaller area or a border, but a tatami fill or other contextually appropriate fill would be more effective in minimizing float for a fill that covers a very large design area. In the design's case of a water Visual Component, the appropriate fill might be a ripple fill for visual effect.

Following the initial path determination, a path-smoothing algorithm is applied (e.g., Gaussian smoothing, Bézier curve fitting). This reduces overtly sharp turns in the stitch path, optimizing for machine performance. (e.g., for satin stitches in particular, the system will generally add pull compensation, which slightly extends stitches beyond the object's boundary to account for the fabric pull-in that occurs during the stitching process.) The LDM then works with the GDM, which determines the final Z-ordering of each layer with a Fill Type.

### 3.2.2. Second Variation

In another implementation, the LDM uses a hierarchical diffusion model to generate stitch decisions per-Manufacturable-Component and per-Stitchable-Layer. The output decisions are the Stitch Layers, along with decisions like their entry/exit points, Functional Stitch Type/Underlay Pattern/Fill Stitch Type/Border Stitch Type, stitch directions, and thread density. The model is pre-trained on examples of input embroidery-friendly designs, high-level embroidery decisions, and stitch decision output for each Manufacturable Component and layer number. This teaches the model how to mimic qualities of good stitch decisions implicitly described by the examples. Adversarial training may be used to further tune the model on more explicit examples of good vs bad stitch decisions, for example, inputs according to particular metrics (e.g., physical robustness and/or artistic value).

During training, additional sub-models/branches and outputs are used to help the diffusion model learn how to visualize its decisions and thus assess the decisions using visual features. The diffusion model takes the embroidery-friendly design and Context as input and feeds it through a context encoder, converting it into a vector of numbers representing the embroidery intent. It then goes through each Manufacturable Component and layer in the order determined by the GDM. The Manufacturable Component image, layer number, and GDM decisions for the Manufacturable Component will be encoded so that it may be output as a vector of numbers representing the current steps and decisions in the embroidery plan.

The diffusion model then generates the stitch decisions for the current layer for the current Manufacturable Component (such as entry and exit points, stitch directions, density, and walk path/fill pattern). The model generates an intermediate vector of features representing these decisions during this process. This vector captures the current decisions and the decisions thus far, and this is used as additional input to condition the diffusion model for generating the decisions for the next embroidery step.

The specialized techniques (such as path smoothing and stitch direction determination) described in Example 1 may be used to further post-process the stitch decisions to ensure they are practical which can happen at intermediate timesteps and at the final timestep. Furthermore, the specialized techniques may be used to generate prior hints to feed to the diffusion model as part of the current-step-decisions input.

After generating the stitch decisions, there may have been some refinements to the GDM decisions such as the overall entry and exit points per Manufacturable Component and Fill Type per Manufacturable Component. These changes could be fed back up to the GDM to allow the GDM to further refine its decisions about entry/exit points and Fill Type. If the GDM employs a diffusion model, it proceeds through one or more further denoising timesteps. If the GDM changes significantly, the LDM may be run again to generate another candidate plan or variation. This loop may be repeated for some number of iterations. Each set of stitch decisions can then be translated into machine stitch instructions.

The LDM generates detailed stitch instructions for each Stitch Layer from the stitch decisions. The LDM interacts with the GDM and Trainer to ensure the accuracy and quality of the stitch plans. Once all the layers are determined, the system generates specific stitch commands, including mechanically necessary “non-decorative” stitching like placement stitches and tie-in/tie-off stitches at the beginning and end of each color change. (Tie-in and tic-off stitches help secure the entry/exit for each color section, which helps prevent unraveling.)

A physical simulation (physics-based “embroidery machine simulator”) is employed to predict how stitches will interact with the fabric, which provides feedback for refinements to the stitch plan to prevent issues like puckering or distortion. This simulation assists in adjusting for thread tension/fabric pull. The results from this simulation feed back into the GDM and LDM, potentially cascading adjustments to the stitch plan. The system also considers machine-specific optimizations, taking into account the capabilities and limitations of specific embroidery filetypes and machine models from different manufacturers (e.g., including optimizations for multi-needle machinery, if available, that can handle faster color changes or differences in output filetype, for example EXP or OFM).

The LDM works with the GDM to ensure that the overall embroidery plan maintains a consistent style and fidelity across all Manufacturable Components and Visual Components and provides consistency in error handling and constraint handling. This process could result in multiple output options, which could all be visualized and ranked by the ranker for presentation to the Verifier.

The Visualizer renders the embroidery-friendly design image and high-level embroidery plans as human-friendly visualizations. The Visualizer uses 3D rendering techniques to create these visualizations (thread modeling, stitch geometry generation, fabric simulation, stitch-fabric interaction, lighting/shading). The Visualizer interacts with the Verifier and Ranker to display the design and receive feedback using an efficient, internally consistent method of structured data exchange (e.g., an API). The Visualizer can generate final embroidery renderings of stitch plans and diagrams of high-level embroidery decisions per-Manufacturable-Component and per-Stitchable-Layer. The Visualizer uses 3D rendering techniques to create these visualizations (e.g., thread modeling, stitch geometry generation, fabric simulation, and stitch-fabric interaction, lighting/shading).

The Ranker scores and reorders variations of embroidery stitch plans based on predefined criteria. The criteria may include metrics such as physical robustness and COGS, artistic appearance and semantics (e.g., how well the plan matches the Verifier's intent), and how well the plan matches the style of a reference plan (if provided). The Ranker filters out plans that do not meet a minimum threshold. The Ranker interacts with the Visualizer, Verifier, and Digitizer to optimize the design. The Ranker filters out plans that do not meet a minimum threshold. The Ranker interacts with the Visualizer, Verifier, and Digitizer to optimize the design. The Ranker ensures that the most promising embroidery stitch plans are presented to the Verifier for selection. The ranker employs a multi-input neural network architecture designed to evaluate embroidery plans. A CNN branch processes spatial features (to capture patterns in stitch layouts, densities, and color distributions), and an FFNN branch processes non-spatial features. The FFNN branch ingests a vector of numerical and categorical features, appropriately encoded and normalized. The FFNN consists of multiple dense layers with rectified linear unit activations, leveraging batch normalization and dropout to enhance learning and accuracy. The two branches work in tandem to provide a holistic result, with the outputs merged for final scoring. The results with final scoring are ranked, and a single result (or selection of results) is then presented to the Verifier for selection of the final design plan and approval to move forward.

The Digitizer reviews the final design as approved by the Verifier and provides expert feedback and corrections to the embroidery design. The Digitizer interacts with the Ranker, Manufacturing, and Inspector to ensure the design meets quality standards. The Digitizer (either an expert or a system trained to function as an expert) uses a multi-criteria evaluation model trained on historical data to evaluate embroidery plans. The model considers multiple criteria in evaluating the plan, such as stitch efficiency, predicted physical robustness or durability, aesthetic quality, and manufacturability (reviewing the plan against machine and physical constraints, like stitch density issues, improper layering, commands or combinations of commands that have a likelihood to cause thread breakage, or other violations of commonly-accepted ‘best practices’ in machine embroidery. The Digitizer provides expert feedback and corrections to the embroidery design. The Digitizer interacts with the Ranker, Manufacturing, and Inspector to ensure the design meets quality standards based on the described criteria. The Digitizer reviews the Verifier-selected embroidery plan(s) and makes correction suggestions to be evaluated and performed by the GDM and LDM. The corrections are stored in the system's database for future reference and learning.

Manufacturing implements the finalized embroidery design. Manufacturing interacts with the Digitizer and Inspector to produce the physical embroidery. Manufacturing implements the finalized embroidery design. The Manufacturing process involves running the embroidery machines for a given stitch file and identifying any physical issues that were not caught before. If there are issues, the embroidery stitch file returns to the Digitizer for corrections.

The Inspector reviews the embroidery design and provides feedback. The Inspector interacts with the Digitizer, Manufacturing, and TED to ensure the design's quality and accuracy. The Inspector reviews the embroidery design and provides feedback. The Inspector interacts with the Digitizer, Manufacturing, and Training Examples Database (TED) to ensure the design's quality and accuracy. The Inspector identifies any physical issues with the embroidery and notes them for further corrections. The feedback from the Inspector is stored in the system's database for future reference and learning.

The Trainer collects inputs, outputs, and human feedback from the Verifier, Digitizer, and Inspector. Based on the collected data, the Trainer fine-tunes the Preprocessor, GDM, and LDM. The Trainer interacts with the TED to store and retrieve training examples. The Trainer collects inputs, outputs, and human feedback from the Verifier, Digitizer, and Inspector. Based on the collected data, the Trainer fine-tunes the Preprocessor, GDM, and LDM. The Trainer interacts with the TED to store and retrieve training examples. The Trainer ensures that the system improves over time by updating the parameters of the various modules based on the feedback and corrections received.

The TED stores feedback and corrections from the Verifier, Digitizer, and Inspector. The TED interacts with the Trainer to update the parameters of the Preprocessor, GDM, and LDM, improving future embroidery designs. The Training Examples Database (TED) stores feedback and corrections from the Verifier, Digitizer, and Inspector. The TED interacts with the Trainer to update the parameters of the Preprocessor, GDM, and LDM, improving future embroidery designs. The TED ensures that the system has access to a comprehensive set of training examples for fine-tuning the modules.

The Context Selector provides additional information to the GDM to aid in generating high-level embroidery plans, using a database to store predefined context options and user-specific preferences, and leveraging an efficient, internally consistent method of structured data exchange (e.g., an API) to communicate relevant context to the GDM. A machine-learning model could be employed to suggest contexts based on known variables. The Context Selector interacts with the GDM (via the ITS) to enhance the design process. The Context Selector provides additional information to the GDM (via the ITS) to aid in generating high-level embroidery plans. The Context Selector includes details such as the size of the final embroidery, the substrate type, the product type, the design title and tags, the manufacturer, the machine type and available machine-specific resources, and the Digitizer. The Context Selector interacts with the GDM to enhance the design process by providing relevant information that influences high-level decisions.

The Image/Text/Selector (ITS) provides the initial input data, including the reference design and text prompt, to the Preprocessor. The ITS interacts with the Preprocessor to facilitate the design generation process. The ITS ensures that the Preprocessor has access to the necessary input data to generate the embroidery-friendly design image. The ITS uses image-processing libraries to perform initial preprocessing, an NLP model to interpret or contextualize text content, and an interface to communicate with (and facilitate decision-making by) the Verifier. The ITS provides the initial input data, including the reference design and text prompt, to the Preprocessor. The ITS interacts with the Preprocessor to facilitate the design generation process through an efficient, internally consistent method of structured data exchange (e.g., an API).

### 4.0. EXAMPLE HIGH-LEVEL DIAGRAM

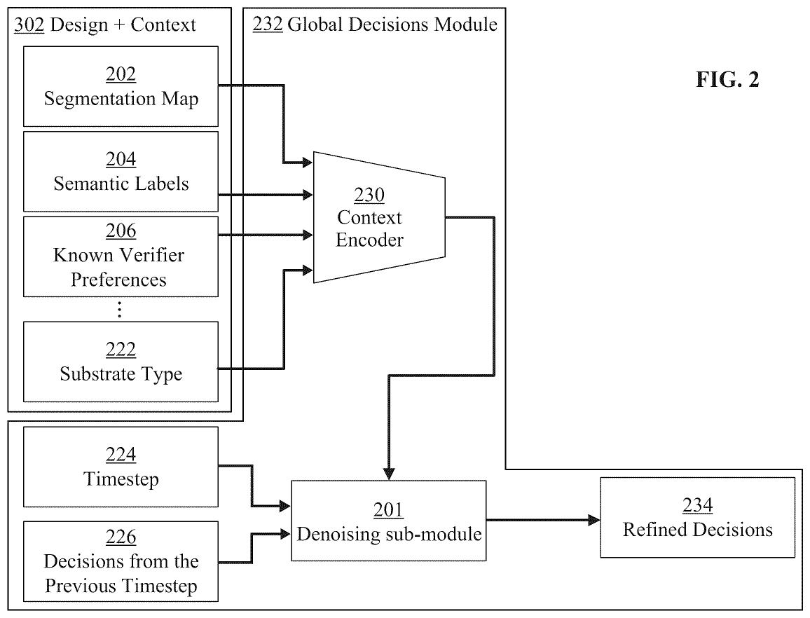

FIG. 2 shows a high-level diagram to generate global decisions. The diagram includes Design+Context 302, which include a Denoising sub-module 201, Segmentation Map 202, Semantic Labels 204, Known Verifier Preferences 206, a Substrate Type 222, a Timestep 224, a Decisions from previous timestep (DFPT) 226, a Context Encoder 230, a Global Decisions Module (GDM) 232, and Refined decisions 234.

Segmentation Map provides a detailed breakdown of the design image into distinct regions. This segmentation aids in identifying and isolating different parts of the design for further processing. The Segmentation Map in the AI-driven embroidery system represents the division of the embroidery-friendly design image into distinct regions. Each region corresponds to a specific part of the design that will be embroidered separately. The Segmentation Map interacts with the Semantic Labels to ensure that each segmented region is accurately identified and labeled. This element is essential for the subsequent steps in the embroidery process, as the Segmentation Map provides a clear and organized structure for the design.

Semantic Labels assign meaningful tags to each segmented region. These labels help in understanding the context and significance of each part of the design, facilitating more informed decision-making. The context represents additional data or parameters that may be required for generating global decisions. This element can include various types of information relevant to the design process.

The Semantic Labels element assigns descriptive tags to each region identified in the Segmentation Map. These labels provide additional metadata about the design, such as identifying specific elements like “dog,” “water,” or “smoke.” The Semantic Labels interact with the Segmentation Map to ensure that each region is correctly annotated. This metadata is used by other element, such as the Global Decisions Module and Local Decisions Module, to make informed decisions about the embroidery process.

Substrate Type indicates the material on which the embroidery will be performed. Different substrates may require different stitching techniques and considerations, making this information necessary for accurate decision-making. The Substrate Type element provides information about the material on which the embroidery will be performed. This includes details about the fabric's density, weave, and other physical properties. The Substrate Type interacts with the Context Selector to ensure that the embroidery plans are tailored to the specific material. This element ensures the physical robustness and quality of the final embroidery product.

Timestep denotes the specific point in the design process. This temporal marker helps in tracking the progress and making time-sensitive decisions.

Decisions from previous timestep (DFPT) provide historical data and decisions made in earlier stages. This information is used to ensure consistency and continuity in the design process.

The Timestep element represents the sequential steps in the embroidery process. Each timestep corresponds to a specific stage in the design and embroidery workflow. The Timestep interacts with the Decisions from previous timestep to ensure continuity and consistency in the embroidery plans. This element manages the iterative nature of the design refinement process.

Context Encoder processes the input data, including Segmentation Map, Semantic Labels, Substrate Type, Timestep, and DFPT. The Context Encoder extracts relevant features and encodes them into a format suitable for the GDM. The Decisions from previous timestep element stores the decisions made in earlier stages of the embroidery process. This includes high-level plans and detailed stitch instructions generated by the Global Decisions Module and Local Decisions Module. The Decisions from previous timestep interact with the Timestep element to provide a historical context for the current stage of the design process. This ensures that the embroidery plans are coherent and built upon previous decisions.

The Context Encoder sub-module processes the contextual information related to the embroidery design. This includes details about the size of the final embroidery, the substrate type, the product type, the design title and tags, the manufacturer, and the Digitizer. The Context Encoder within the Global Decisions Module converts it into a vector of numbers representing the embroidery intent. This sub-module ensures that the embroidery plans are tailored to the specific requirements of the design and the intended application.

The Global Decisions Module (GDM) receives the preprocessed design, metadata, and context information. The GDM generates high-level embroidery plans, including the order of Manufacturable Components, the number of stitch layers, the fill type, and the entry and exit points for each Manufacturable Component. The GDM interacts with the Local Decisions Module to coordinate the design process. This module is responsible for making the decisions that guide the entire embroidery workflow.

Refined Decisions are the output of the GDM. These decisions are detailed and specific, ready for further refinement and implementation in the embroidery process. The Refined Decisions element represents the output of the Local Decisions Module after refining the high-level embroidery plans on a per-Manufacturable-Component and per-Stitchable-Layer basis. This includes detailed stitch instructions for each Manufacturable Component, such as stitch directions, entry and exit points, fill style, and stitch density. The Refined Decisions interact with the Global Decisions Module to ensure that the detailed plans align with the high-level objectives. This element is essential for translating the high-level plans into actionable instructions for the embroidery machine.

### 5.0. EXAMPLE HIGH-LEVEL DIAGRAM FOR GENERATING AND REFINING EMBROIDERY DESIGN

### 5.1. Global Decision-Making Process

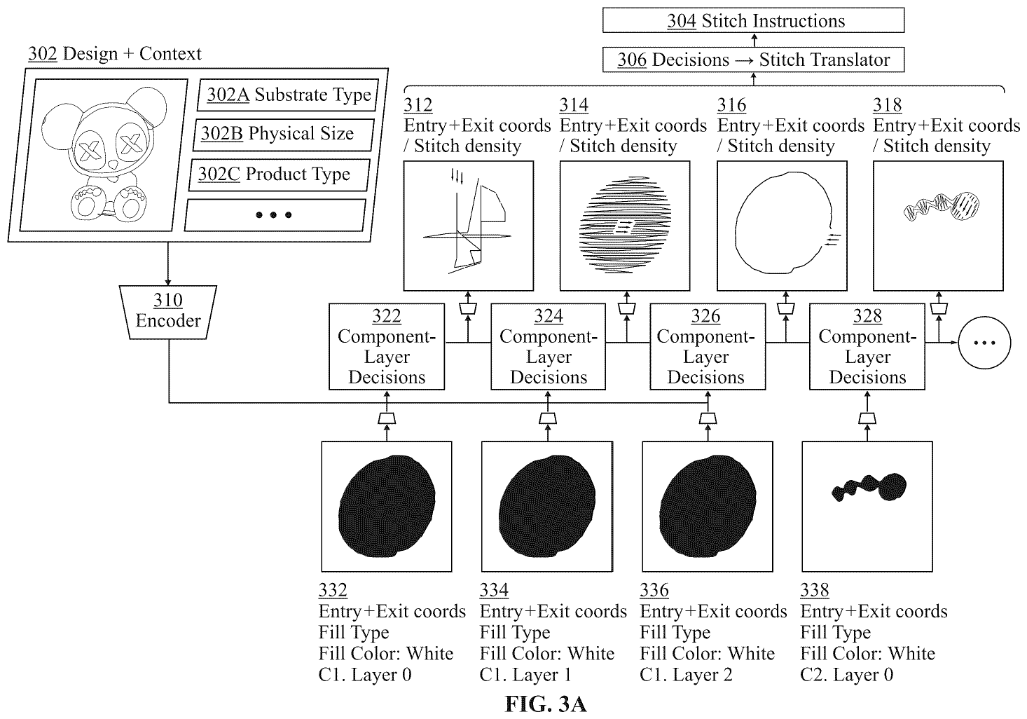

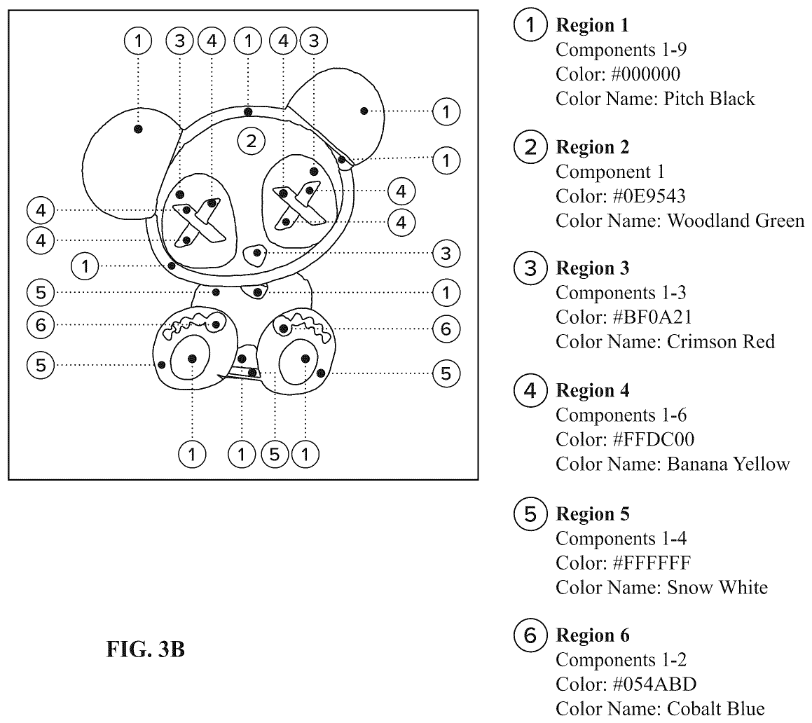

FIG. 3A shows an example high-level diagram for generating and refining embroidery designs. The diagram includes a Design+Context 302, a Substrate type 302A, a Physical Size 302B, a Product type 302, an Encoder 310, a Stitch instructions 304, a Decisions->Stitch Translator (DST) 306, Component-Layer Decisions (CLD) 322-324-326-328, Entry+Exit coordinates (EEC) 332-334-336-338, Entry+Exit coordinates/Stitch density 312-314-316-318. The elements provide the foundational input for the embroidery system. Design+Context 302 includes the design image and contextual information such as the substrate type, physical size, and product type.

Design+Context receives a reference design and a text prompt from a Verifier. This element provides the initial input for the embroidery design process, incorporating the Verifier's requirements and preferences. The Design+Context element interacts with the Context Encoder within the GDM to ensure that the input data is accurately represented and processed for subsequent stages.

Substrate type, Physical Size, and Product type provide additional context information for the design. Substrate type specifies the material on which the embroidery will be applied. Physical Size defines the dimensions of the design area. Product type indicates the type of product that will feature the embroidery. The Substrate Type element specifies the type of material on which the embroidery will be applied. This information is for determining the appropriate stitch types and densities. The Substrate Type element interacts with the Encoder to ensure that the material properties are considered during the design and planning stages.

The Physical Size element defines the dimensions of the final embroidery. This element ensures that the design is scaled appropriately for the intended application. The Physical Size element interacts with the Encoder to maintain the correct proportions and details of the design.

The Product Type element identifies the specific item that will feature the embroidery, such as a jacket or hat. This element influences the design and planning process by providing context-specific requirements. The Product Type element interacts with the Encoder to tailor the design to the specific product.

Encoder processes the input from Design+Context and the additional context information. Encoder translates this information into a format suitable for further processing by the CLD. The Encoder module processes the input data from the Design+Context, Substrate Type, Physical Size, and Product Type elements. The Encoder transforms this data into a format suitable for the Component-Layer Decisions module. The Encoder ensures that all relevant information is accurately captured and represented for further processing.

The Decisions->Stitch Translator module converts stitch decisions into machine-interpretable stitch instructions. This DST module takes input from the Component-Layer Decisions module and generates machine-interpretable instructions for each Manufacturable Component and layer of the design. The Decisions->Stitch Translator ensures that the embroidery plan is executable by the embroidery machine. DST receives the generated stitch decisions from CLD.

The Component-Layer Decisions module generates the detailed stitch decisions for each Stitch Layer of a specific Manufacturable Component in the design. The detailed stitch decisions include information such as entry and exit coordinates, stitch density, and fill type for each Stitch Layer. The Component-Layer Decisions module interacts with the Decisions->Stitch Translator to ensure that each Stitch Layer is accurately represented in the machine-interpretable stitch instructions. CLD refines the high-level embroidery plans from the GDM on a per-Manufacturable-Component and per-Stitchable-Layer basis and is guided by the processed information from the Encoder. CLD generates detailed stitch decisions for each Manufacturable Component, ensuring precise and accurate embroidery.

The Entry+Exit Coords element represents the coordinates for the entry and exit points of the stitches for a Stitch Layer or for Manufacturable Component. This element ensures that the stitching process is efficient and minimizes unnecessary thread movements. The Entry+Exit Coords element interacts with the Component-Layer Decisions to provide precise stitching decisions. EEC ensures that the embroidery machine follows the correct path during the stitching process. The CLD generates the EEC for each Stitch Layer, guided by the EEC (and other high-level decisions) for the Stitch Layer's Manufacturable Component and the processed information from the Encoder.

Stitch Density specifies the density of stitches for each Stitch Layer. Stitch Density ensures that the embroidery has the desired texture and appearance. The Stitch Density element defines the density of the stitches for each Stitch Layer of a Manufacturable Component. This element ensures that the embroidery is both aesthetically pleasing and physically robust. The CLD generates the Stitch Density for each Stitch Layer.

Fill type (FT) defines the fill type for each Manufacturable Component. FT ensures that the embroidery has the correct fill pattern, contributing to the overall design aesthetics. The FT element, representing Fill Type, specifies the type of fill stitch to be used for each layer of a Manufacturable Component. This element influences the texture and appearance of the embroidery. The FT element interacts with the Component-Layer Decisions to select the appropriate fill type for each Stitch Layer.

The C1 and C2 elements, representing Manufacturable Component Identifiers, identify each Manufacturable Component in order within the design. These elements ensure that the stitch instructions are correctly associated with the corresponding design elements. The C1 and C2 elements interact with the Component-Layer Decisions to maintain the integrity and organization of the stitch instructions.

C1.Layer 0, C1.Layer 1, C1.Layer 2 and C2.Layer 0 identify different Stitch Layers in the embroidery design. C1.Layer 0 represents the initial layer of the second Manufacturable Component in stitch order. CLD will use this order information, the high-level decisions for the second Manufacturable Component, and the processed information from the Encoder to generate stitch decisions for this initial Stitch Layer. The high-level decisions associated with the Manufacturable Component include EEC and FT. The CLD will then continue to generate stitch decisions for the subsequent Stitch Layers.

The C1.Layer 1 element represents the subsequent Stitch Layer of the second Manufacturable Component. CLD will use this order information along with the high-level decisions associated with the second Manufacturable Component, the stitch decisions generated for the design thus far by the CLD, and the processed information from the Encoder, to generate stitch decisions for this second Stitch Layer. The CLD will continue for each subsequent Stitch Layer and for each subsequent Manufacturable Component in the design. CLD will keep track and build upon the decisions it has made thus far.

### 6.0. COLOR QUANTIZATION AND CLUSTERING

FIG. 3B depicts a high-level diagram of color quantization and clustering. The process is described above.

### 7.0. EMBROIDERY EXAMPLE

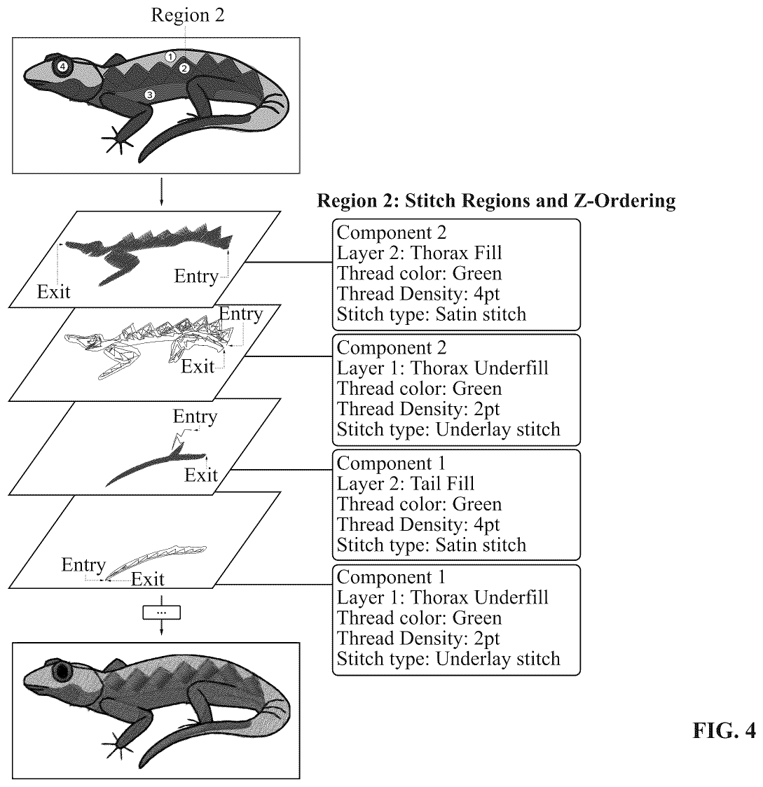

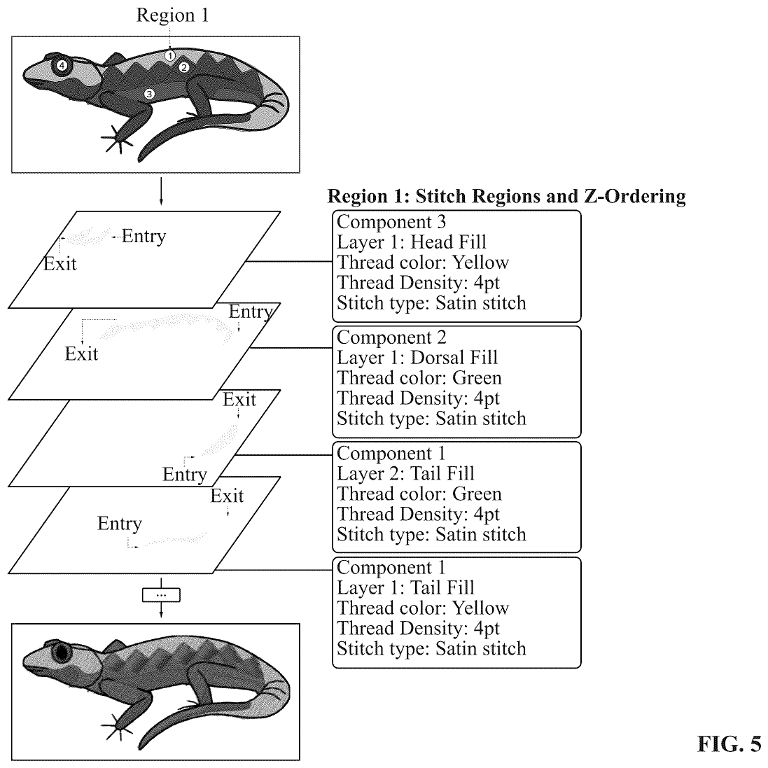

FIG. 4 is an example of stitch regions and Z-ordering. Z ordering is specifically the stacking order of Visual Components, Manufacturable Components, and Stitch Layers from bottom (first stitch layer) to top (last stitch layer) FIG. 5 is an example of stitch regions and Z-ordering.

### 8.0. EXAMPLE COMPUTER ENVIRONMENTS

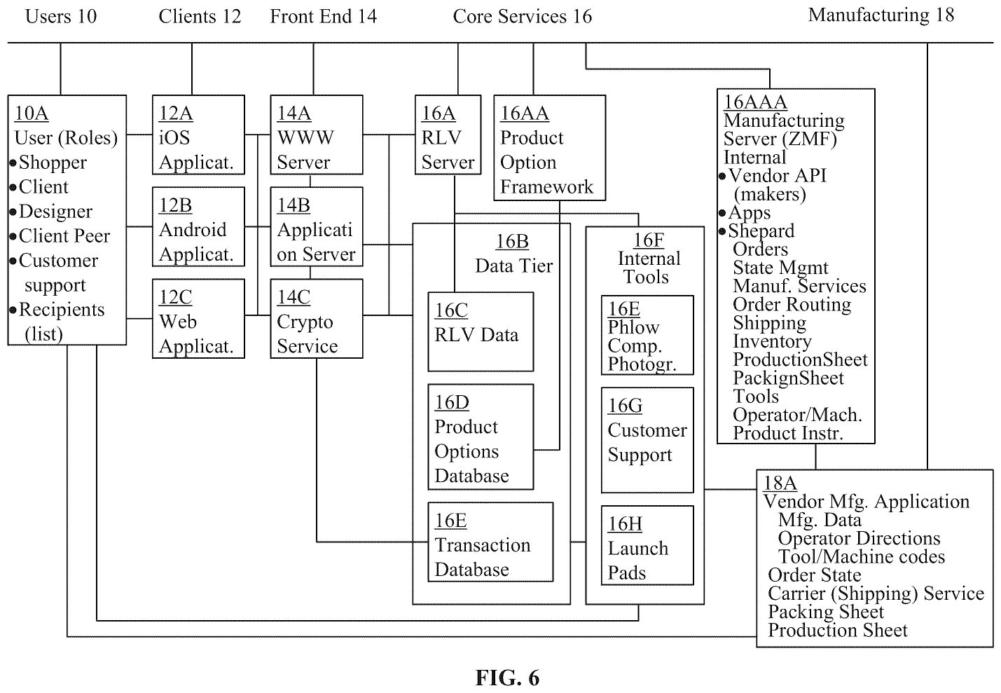

In some embodiments, the presented approach is implemented in a product collaboration platform. The platform allows users, designers, Verifiers, and support engineers to, for example, design and create digital product designs. FIG. 6 describes a computer environment for creating digital designs, manufacturing products, and the like FIG. 6.

A digital design for a product may be captured in, for example, product description data. A hyperlink to the particular location may be created and transmitted from the collaboration platform to a manufacturing server to cause the manufacturing server to generate a final product based on the digital design.

A product may be digital, such as a digital gift card, or physical or digital, such as a physical or digital t-shirt.

FIG. 6 is a block diagram showing an example computer environment. In FIG. 6, users 10 are individuals who create and design digital designs of products; clients 12 correspond to software applications configured to facilitate communications between users 10 and front-end servers 14; core services 16 correspond to software applications and tools configured to facilitate creating and designing of the digital designs and generating manufacturing instructions for manufacturing final products based on the digital designs; and manufacturing 18 corresponds to manufacturing servers and applications configured to manufacture, or cause manufacturing, the final products, and the like.

### 8.1. User Devices

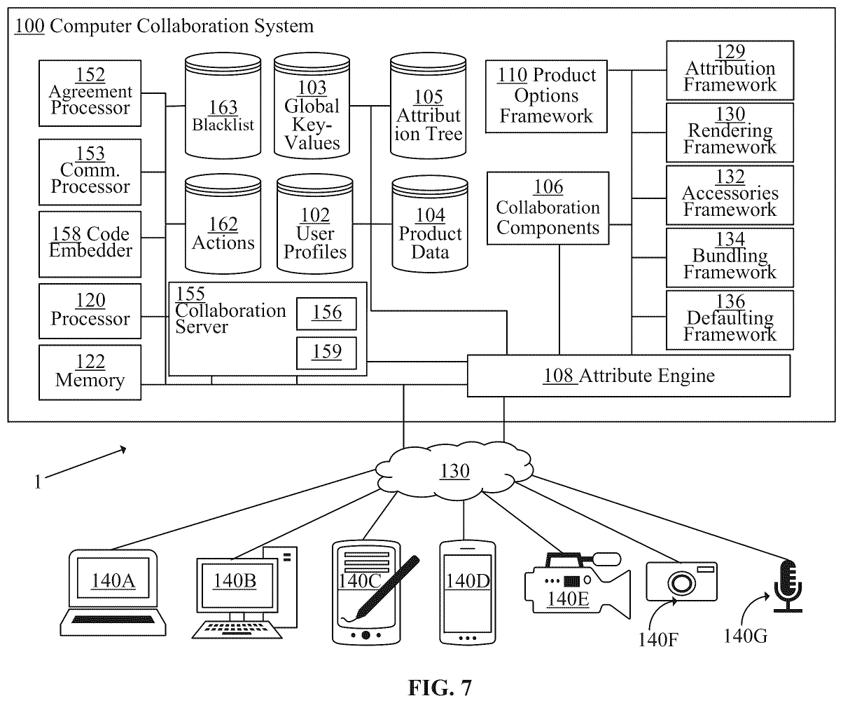

FIG. 6 depicts several examples of users 10. Each user 10 may use its own or shared computer device. Examples of user devices are described later in FIG. 7 (see devices 140A-G).

In some embodiments, examples of user 10 are determined based on the roles that may be assigned to the users. Examples 10A of roles may include a shopper, a client, a designer, a client peer, a Verifier support engineer, a recipient, and the like.

### 8.2. Client Applications

Clients 12 in FIG. 6 refer to client applications implemented in client servers 14 and configured to support requests received from users 10A. Non-limiting examples of clients 12 may include iOS applications 12A, Android applications 12B, Web applications 12C, and the like.

### 8.3. Front and End Servers

Front and end servers 14 refer to computer-based servers configured to process requests received from clients 12 and, in many cases, interact with core services 16 to further resolve these requests. Examples of front-end servers 14 include one or more WWW servers 14A, one or more application servers 14B, and one or more cryptographic servers 14C. Cryptographic servers 14C may be configured to provide cryptographic services for encrypting/decrypting, transmitting, or otherwise communicating data between the entities depicted in FIG. 6.

### 8.4. Core Services

Core services 16 in FIG. 6 refer to servers and services implemented in a role-based collaboration platform configured to provide functionalities for creating and designing digital designs, handle collaboration requests, and facilitate the customization requests received from users 10.

In some embodiments, a customization process performed by a user of users 10, intended to generate a digital design of a customized product, is captured in so-called product description data, which may be translated into a manufacturing description comprising product and manufacturing instructions.

The product and manufacturing instructions may include digital design specifications, data, and code needed to manufacture a custom product. That may include instructions for generating, for example, a 3D geometry for digital final products. This may also include generating instructions for generating 2D and 3D patterns that may be used to cut, cast, or form physical or digital elements of physical or digital final products. The patterns may be parametric, i.e., they may have parameters that, through encoded relationships, adjust the form of the pattern for a specific need.

For instance, a set of 2D patterns for a t-shirt graded based on size may become a parametric pattern by interpolating grade curvatures. A single parametric value, usually called a ‘size,’ may set the automatic grading.

The product instructions may also include 2D and 3D models used to form, through additive manufacturing or subtractive manufacturing, portions of a product. The models may be parametric, i.e., they may have parameters that, through coded relationships, adjust the form of the model for a specific need. For instance, a set of 3D models may represent a bike helmet. Each model may fit a statistically normed human head of a particular age. A coded relationship between the models may allow for interpolating the set of models for a particular age. A single parametric value may set the automatic interpolation. The single parametric value, in this case, is usually called an ‘age.’

The product instructions may also include material properties, such as the physical or digital material used to form a product from a pattern. Some material properties may be parametric, i.e., they may be selected or changed during the manufacturing process.

The properties may also include a body color. For instance, the color of a fabric may be selected for manufacturing a t-shirt. According to another example, the plastic color may be selected for manufacturing a bike helmet.

The properties may also include a body texture, such as the fabric weave of a t-shirt, which may be specified to be smooth or slubby. For instance, the surface of a plastic bike helmet may be polished or satin. Each property is necessarily specific to each class of materials. Examples of materials and properties may include a fabric (such as a weave or knit type, a fiber type (e.g., cotton, wool, flax, polyester, polypropylene), a thread size, a thread count, a color, an integral design (e.g., ikat, knit, tapestry, etc.), a bolt width, a selvage type, a surface (e.g., hand), and the like.

The properties may also include plastics, which may include sub-properties such as color, surface quality (e.g., a bidirectional luminance function), melting point, impact resistance, a forming method (e.g., thermoplastic, cast, etc.), a type (e.g., acrylic, polypropylene, etc.), and the like.

The properties may also include metals, which may include sub-properties such as a type (e.g., aluminum, steel, copper, brass, etc.), a color, a surface quality (e.g., a bidirectional luminance function), a melting point, a tensile strength, a shear strength, toxicity, and the like.

The properties may also include non-woven specified by a type (paper, felt, Tyvek, etc.), a color, a surface quality (e.g., a bidirectional luminance function), a surface type (e.g., hot pressed, natural, textured, etc.), a weight per square meter, an acid content, a compatible media, coating, and the like.

The properties may also include metamaterials that may be described as a combination of multiple materials created during manufacturing. For instance, plastics with various properties may be mixed during fused deposition manufacturing to provide a physical or digital product with gradations of flexibility, durometer, and the like. According to another example, a mix of metal alloys with various properties may be deposited during the laser sintering of metals, resulting in a product composed of gradations of metallic properties. According to yet another example, during high-resolution uv-printing, layers of the uv-cured material with different refractive indices may be deposited, resulting in a large variety of optical effects.

The properties may also include embellishments such as trim colors, designs, and applied ornaments. The trim colors may indicate the color of the edging around the sleeve of a T-shirt, the color of the trim around the base of a bike helmet, and the like.

The designs may indicate a custom printed front of a t-shirt, a custom thermal printed design to the side of a bike helmet, and the like.

The applied ornaments may indicate rhinestones on a t-shirt, holographic spangles on a bike helmet, and the like.

Some properties may apply to a large class of products and allow for a limited set of properties to be transferred from one product to another. Other properties may be specific to a particular product or manufacturing method.

It may be appreciated that much of the novel art of the system and method is in enumerating the constraints imposed by manufacturing a specific custom product and crafting these constraints as a set of product option key/value pairs. These manufacturing constraints are propagated through the entire system and method, and using these product option key-values allows for manufacturing a series of custom products that meet these physical or digital constraints.

Referring again to FIG. 6, in some embodiments, core services 16 refer to services implemented in a role-based collaboration platform. In the example, core services 16 may be provided by one or more real-view (RLV) servers 16A and a product option framework 16AA. RLV servers 16A and product options framework 16AA may use one or more data tier databases 16B, including RLV Data 16C, a product options database 16D, a transaction database 16E, and the like.

In some embodiments, core services 16 may also utilize internal tools 16F, such as computational photographic tools 16E, Verifier support tools 16G, launch pads tools 16H, etc.,

Product option framework 16AA is also called a persistent design data framework. The framework data may include a product options set, which may include a set of product options pertaining to a specific product type. It usually contains the product instructions (e.g., Collaboration Components 106 in FIG. 7) for manufacturing or producing the product.

In some embodiments, product options framework 16AA is configured to provide services for transforming ProductOption key/value pairs (e.g., manufacturing constraints) from one product to the other. Transforming the ProductOption key/value pairs from one product to another may require, for example, transforming the color space (e.g., sRGB to CMYK US Web Coated (SWOP) v2), transforming an image from raster to vector, and resizing the image for the fit.

In some embodiments, there are two basic types of product instructions: (1) fixed (which includes the instructions for the product that are fixed and not customized) and (2) custom (which contains the logic to transform a user interface parameter into a product instruction).

In some embodiments, the product option set contains the logic to enumerate each customizable option in a manner that presents a complete user interface to change the parametric product instructions.

The instructions for manufacturing a customized product are usually parametric. The parameters include the size of the customized product (this can be multi-dimensional and include width, height, and depth). The parameters may also relate to human size or age. The parameters may also be custom and based on biometric information.

The parameters may also include a Manufacturable Component body color, a Manufacturable Component body texture, a trim body color, a trim body texture, a design area, and the like.

In some embodiments, a product option may be represented as a key/value pair. The key/value pair is a label that may span individual products and represent a class of products. The keys of pairs may include a material type, a color, a size, and the like.

The value in a key/value pair is a specific discrete or continuous value that sets a manufacturing instruction. Examples of discrete (enumerated) values may include a discrete type of fabric such as cotton, cotton-polyester blend, silk, and the like. The discrete values may also include specific colors, such as white, navy, black, and the like.

Examples of continuous values of key/value pairs may include a single element, such as length or a ribbon, a vector, such as the size of a frame for a print (width (in inches) or height (in inches)), or the size of a box for the European countries, such as a size of a box for the EU (width (in millimeters), height (in millimeters), depth (in millimeters)).

The values may also reference a known file type, such as an image for the t-shirt design, an embroidery file for the back of a jacket, an engraving design for a bracelet, and the like.

In some embodiments, values in key/value pairs may include a set of graphic primitives for a design, such as an image, a line, a circle, a rectangle, a text, a group, and the like.

The product option key values may have default values. Default values are pre-set values that will produce a product without changing any key/value pairs through customization. When key values are changed, they may produce a product option framework event chain. A product options framework event chain is a journal of each key-value change ordered in time.

A product type may be represented by a product option key-value. Using this option type, one product type may be associated with another through a well-known relationship.

In some embodiments, a product options framework event chain includes one or more products, and the chain may represent or memorialize an event. The products may represent or memorialize an event. Examples of events may include weddings, birthdays, anniversaries, graduations, national holidays, reunions, and the like.

Many products fit into an event chain. For example, the products that fit into a wedding event may include the following products: save the date products, invitations, RSVPs, bachelor party invite products, bachelorette party invite products, party favors products, gift registry cards, place cards, napkins, wedding programs, wedding gifts, thank-you cards, wedding keepsake photos, and the like.

Examples of products that may be appropriate for a birthday event include invitations, RSVPs, party bags, party keepsake photos, and the like.

In some embodiments, in a product option set event chain, a key/value pair encodes the next product in the chain. For example, an invitation may be chained to an RSVP card. A key-value may also encode the role of the chained event. For example, a chained RSVP card key-value may further include a recipient of the invitation as the sender role for the RSVP card.

A key/value pair may also encode the shared properties used to set the chained product's properties. For instance, a design for the invitation may be shared with the RSVP card. A key-value may also encode the timing for the chained product. Typically, the event chain properties are custom (e.g., parametric), and a product designer may change them to fit a specific product set.

In an embodiment, a product option framework is configured to generate a product option framework user interface. Accordingly, each product option set is associated with logic and code to build a user interface element for each parametric product option. Furthermore, each product options set contains style hints so that each user interface element may be artfully placed to produce a high-quality user experience.

Typically, user interface elements are designed to match each class of values in all products covered by a product options framework. New user interface elements may be added as the product categories expand. The user interface elements may include a design view, a color editor, a font editor, a size selector, a texture selector, a text editor, a fabric swatch selector, a product configurable image, and the like.

In some embodiments, a product options framework cooperates with a user product renderer that may be implemented in, for example, a RealView server 16A. The user product renderer may be configured to render views of a custom product as it is already manufactured. Typically, it uses a product option set of key-values as input. It creates one or more run-time assets using computational photography of the manufactured product.

### 9.0. EXAMPLE MANUFACTURING SYSTEM

Referring again to FIG. 6, manufacturing instructions may be communicated from core services 16 to manufacturing 18, including one or more manufacturing servers 16AAA. Servers 16AAA may receive the manufacturing instructions, process the instructions, and communicate with a vendor manufacturing application 18A to generate, for example, manufacturing data, operator directions, tool/machine codes, and the like. The application may also generate information about an order state, a packing slip, a production sheet, etc., Some of that information may be communicated to a carrier (shipping) service selected to deliver the final products to the recipients.

A final product may be manufactured using markups. A markup for, for example, a body color of a product may be made by specifying a distinct and separate color for the BodyColor key-value. A markup for the trim color of a product may be made by specifying a distinct and separate color for, for example, a TrimColor key/value pair. A markup for a design area of a product may be made by specifying a specific marker type (e.g., a removable linear markup, a digital markup, or a digital field markup) for a design-area image.

As described above, a manufacturing process may pertain to manufacturing a digital product as well as manufacturing a physical or digital product. Since the manufacturing instructions for generating a product are generated based on a plurality of key/value pairs for a digital design of the product, in some situations, the same manufacturing instructions may be used to manufacture the digital product as well as to manufacture the physical or digital product.

Then, the manufacturing system may traverse the images stored in the local image cache and determine an optimal color palette for that collection of images.

Subsequently, the manufacturing system may convert the images in the local image cache from 32-bit RGBA format to 8-bit Indexed color.

Then, the manufacturing system may embed a digital watermark that encodes the input Key ValueJournal's UUID in the 8-bit indexed color image cache.

Next, the manufacturing system may begin encoding the image file. For example, the manufacturing system may write the header bytes, write the Logical Screen Descriptor bytes, write the found color palette as a gif Global Color Table, write the gif 8-bit character application name, and embed metadata as a comment (or a watermark) which encodes the input Key ValueJournal's UUID.

Next, the manufacturing system sets a FrameCount to 1 and proceeds to process each frame in the image file. The processing includes checking if there is an image in the 8-bit indexed color image cache; if so, the manufacturing system continues; otherwise, it proceeds to take the next image.

To continue, the manufacturing system writes the GIF Graphic Control Description for the FrameCount and then processes the first 8-bit indexed color image cache into blocks of 255 LZW compressed bytes.

Next, the manufacturing system writes the compressed bytes and removes the first image from the 8-bit indexed color image cache. Then, the manufacturing system increments the FrameCount and repeats the process for the next frame.

Once the manufacturing system processes all frames, it writes the file terminator (such as an ASCII code for zero) to the image file and outputs the manufactured GIF product.

At this point, executing the manufacturing instructions to manufacture the product ends, and the product's manufacturing is completed.

### 10.0. EXAMPLE PRODUCT COLLABORATION PLATFORM

In some embodiments, the approach presented herein is implemented in computer systems hosting a product collaboration platform. Alternatively, the approach may be implemented in one or more computer systems that communicate with the collaboration platform but that do not actually host the platform itself. For the clarity of the description, it is assumed that the computer environment supporting the approach presented herein is implemented in the product collaboration platform.

FIG. 7 is a block diagram showing an example of the collaboration platform. FIG. 7 is a block diagram showing an example of a role-based collaboration platform. In the example depicted in FIG. 7, a computer collaboration system 100 includes a user profiles database 102, a global-key-values database 103, a product data definitions database 104, an attribution trees database 105, Collaboration Components 106, a product options framework 110, an attribute engine 108, one or more processors 120, one or more memory units 122, and one or more frameworks 129-136.

Furthermore, computer collaboration system 100 includes a Collaboration Server 155 (including a monitoring system 156 and a request analyzer 159), one or more blacklist databases 163, one or more actions databases 162, an agreement processor 152, a communications processor 153, and a code embedder 158. Computer collaboration system 100 may communicate directly or via one or more communications networks 130, with one or more user computers 140A-140G, all described in detail later.

Computer collaboration system 100, shown in FIG. 7, is provided herein to illustrate clear examples and should not be considered limiting. Other computer collaboration systems may include additional components or modules such as computer servers, various input/output devices, and additional software and hardware components or modules not depicted in FIG. 7. Other computer collaboration systems may be implemented in cloud-based systems, distributed computer networks, etc., Other computer collaboration systems may include fewer components or modules than, for example, computer collaboration system 100, as shown in FIG. 7.

Digital product collaboration platform 100, shown in FIG. 7, may support a variety of collaboration sessions. The sessions may be established between two or more users, and the types of collaboration sessions may depend on the roles assigned to the users who participate in them.

Referring again to FIG. 7, digital product collaboration platform 100 is provided herein to illustrate clear examples and should not be considered limiting. Other computer collaboration systems may include additional components or modules such as computer servers, various input/output devices, and additional software and hardware components or modules not depicted in FIG. 7. Other computer collaboration systems may be implemented in cloud-based systems, distributed computer networks, etc., Other computer collaboration systems may include fewer components or modules than, for example, the digital product collaboration platform 100 shown in FIG. 7.

Attribute engine 108 may be configured to facilitate role-based collaboration of customizable products according to roles assigned to users and according to manufacturing constraints set forth for the products. Attribute engine 108 may be configured to, for example, interact with Collaboration Components 106, product options framework 110, frameworks 130-136, and user devices 140A-140D to allow the users using devices 140A-140G to collaborate in customizing interactive designs offered by platform 10.

In some embodiments, attribute engine 108 may be configured to interact directly with users of user devices 140A-140G. In other embodiments, attribute engine 108 may be configured to interact with users of user devices 140A-140G via a computer network 131, as shown in FIG. 7.

In some embodiments, attribute engine 108 comprises various additional modules, including a database interface (not shown), a manufacturing interface (now shown), an imaging device (not shown), a graphical representation module (not shown), a correlation module (not shown), and an instructions generating module (not shown). Other additional modules may also be included in attribute engine 108.

A database interface may be configured to interact with ZIG files, providing real-time configuration data for customizing the products.

A manufacturing interface may be configured to translate the key/value pairs from the ZIG files into a plurality of manufacturing instructions compatible with executable programs of a manufacturing system for creating a corresponding product.

An imaging device may be configured to detect visual differences between the manufactured product and a synthetic rendering of the custom product.

A graphical representation module may be configured to construct a graphical representation of the product using a plurality of modified key/value pairs to indicate changes in appearance between the manufactured product and the synthetic rendering.

To determine differences, a correlation module may be configured to correlate the modified key/value pairs with the original key/value pairs.

An instruction generation module may be configured to generate additional manufacturing instructions based on the determined differences; enabling the manufacturing system to produce a product more closely resembles the synthetic rendering of the custom product.

Computer network 130 may be implemented as any type of communications network, including a local area network (LAN), wide area network (WAN), wireless network, secure virtual LAN (vLAN), secure virtual WAN (vWAN), and the like.

User devices 140A-140G may include any communications devices configured to facilitate communications between users and digital product collaboration platform 100. In the example depicted in FIG. 7, a user device 140A is a laptop, a user device 140B is a personal computer, a user device 140C is a personal assistant device, a user device 140D is a mobile device such as a smartphone, a user device 140E is a video camera, a user device 140F is a digital camera, and a user device 140G is a microphone configured to capture audio data and communicate the audio data to digital product collaboration platform 100.

The types and counts of user devices 140A-140G are not limited to the examples shown in FIG. 7. For example, even though FIG. 7 depicts only one laptop 140A, one personal computer 140B, one personal assistant 140C, one smartphone 140D, one video camera 140E, one digital camera 140F, and one microphone 140G, platform 100 may include a plurality of laptops 140A, a plurality of personal computers 140B, a plurality of personal assistants 140C, a plurality of smartphones 140D, a plurality of video cameras 140E, a plurality of digital cameras 140F, and a plurality of microphones 140G. In other examples, user devices may include fewer devices than those depicted in FIG. 7. In other examples, the user devices may include devices not depicted in FIG. 7.

Collaboration Server 155 may be implemented in software, hardware, or both. It may be configured to cooperate with monitoring system 156 to provide monitoring capabilities to platform operators and a third-party monitoring service. The capabilities may include the ability to intercept the contents of communications exchanged between the collaboration platform users, determine whether the communications meet the terms of the collaboration agreements, and pursue actions to address violations when the communications fail to meet the rules set forth in the agreements.

Collaboration Server 155 may be part of digital product collaboration platform 100, as shown in FIG. 7. Alternatively, a collaboration server may be a system implemented in a computer server (not shown) that is separate from digital product collaboration platform 100.

Collaboration Server 155 may comprise monitoring system 156iments in some embodiments, as shown in FIG. 7. In other embodiments, Collaboration Server 155 may be separate from monitoring system 156.

In some embodiments, Collaboration Server 155 is configured to transform ownership and license agreements, embedded in a plurality of key/value pairs journaled during a collaboration session between collaborators, into a graph-network and then into an ownership-agreement tree. The ownership-agreement tree may be used to represent the ownership and license agreements between the collaborators participating in the collaboration session.

Collaboration Server 155 may also be configured to evaluate the ownership-agreement tree with respect to a plurality of role-based communications channels established between the collaborators for each constraint of a plurality of constraints on each collaborator of the collaborators.

The constraints may be identified from the ownership agreement tree. They may include rules, guidance, conditions, specifications, and provisions that set forth how collaborators may communicate with each other during collaboration sessions. Examples of constraints may include agreement constraints (such as ownership agreements, license agreements, and the like), use constraints (that impose limits on editing and modifying design elements produced by collaborators), communications constraints (that impose limits to durations of the sessions, inactivity during the sessions, and the like), interactions constraints (such as contractual constraints and professional-conduct constraints), and content constraints (imposing blacklists and whitelists on the communications). Some of the constraints may be system-wide constraints and apply to one or more, or all, collaborations supported by a collaboration platform.

In some embodiments, monitoring system 156 is implemented as a module of Collaboration Server 155, as shown in FIG. 7. In other embodiments, monitoring system 156 is implemented as a server (not shown) separate from Collaboration Server 155.

Monitoring system 156 may be configured to cooperate with Collaboration Server 155 in terms of tracking and monitoring the communications exchanged between collaborators, generating transcripts of the communications, and parsing the transcripts to determine the characteristics of the corresponding data streams.

Monitoring system 156 may also be configured to assist Collaboration Server 155 in evaluating an ownership-agreement tree with respect to role-based communications channels established between the collaborators to determine whether any communications exchanged between the collaborators violate any constraints of a plurality of constraints.

In some embodiments, digital product collaboration platform 100 comprises agreement processor 152, communications processor 153, processor 120, and monitoring system 156. Among other things, components 152-153, 120, and 156 are configured to support Collaboration Server 155 in journaling key/value pairs that capture ownership and license agreements. They may also be configured to transform the key/value pairs into a graph network and then into an ownership-agreement tree.

Components 152-153, 120, and 156 may also be configured to support Collaboration Server 155 in evaluating the ownership-agreement tree with respect to a plurality of role-based communications channels established between the collaborators for each constraint on each collaborator.

Moreover, components 152-153, 120, and 156 may support Collaboration Server 155 in determining whether one or more communications, monitored in the plurality of role-based communications channels, violate one or more constraints of the plurality of constraints.

That determination may include, among other things, generating transcripts of data intercepted from data communications channels supporting communications sessions established between collaborators. For example, components 152-153, 156, and 120 may generate a video transcript of the video chat and associate the transcript with the corresponding collaboration session. Components 152-153, 120, and 156 may provide the transcript's content, including video frames, audio clips, and chat texts, to monitoring system 156 and Collaboration Server 155.

Components 152-153, 120, and 156 may also be configured to collect statistical and diagnostic information about communications sessions established to support collaboration between users. For a communications session, the information may include information about the duration of the session, a count of retransmissions performed during the session, an indication of whether the session ended abruptly, and the like.

### 11.0. PROCESS FOR GENERATING EMBROIDERY STITCH INSTRUCTIONS USING AI-BASED EMBRODIERY SYSTEM

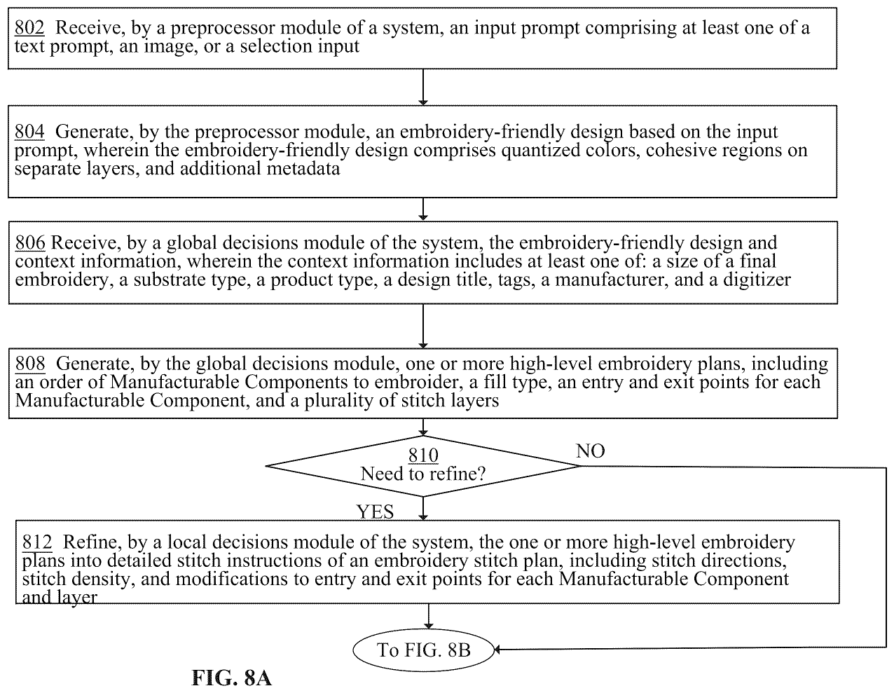

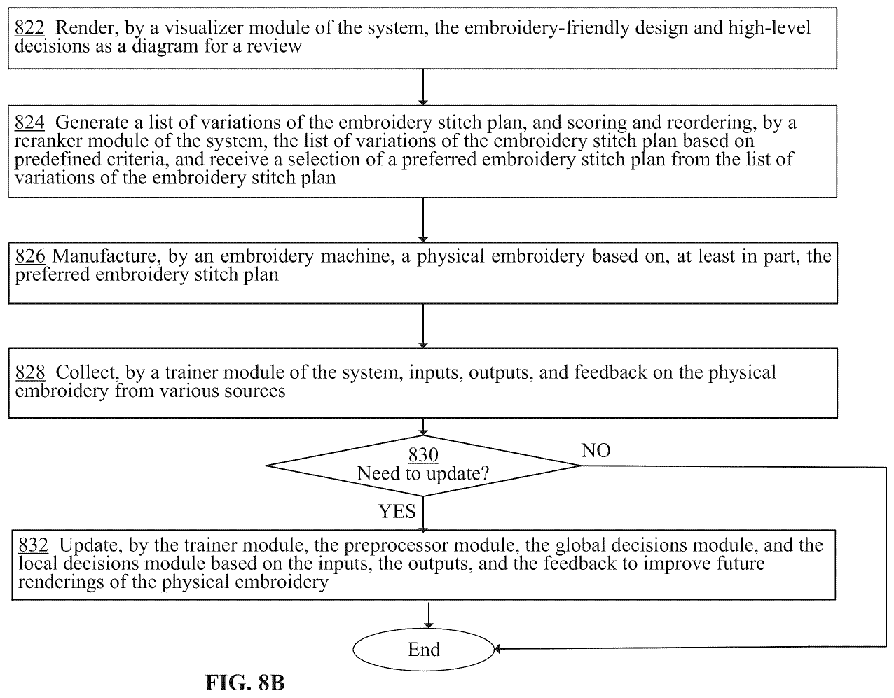

FIG. 8A is a flow chart depicting an example process for generating embroidery stitch instructions using AI-based embroidery system. In FIG. 8A, in step 802, the preprocessor module of the system receives an input prompt comprising at least one of a text prompt, an image, or a selection input. In step 804, the preprocessor module generates an embroidery-friendly design based on the input prompt. The embroidery-friendly design comprises quantized colors, cohesive regions on separate layers, and additional metadata. The preprocessor module 802 interacts with the input data to process the reference design and text prompt provided by the Verifier.

In step 806, the Global Decisions Module receives the embroidery-friendly design and context information. The context information includes at least one of: a size of a final embroidery, a substrate type, a product type, a design title, tags, a manufacturer, and a Digitizer.

In step 808, the Global Decisions Module generates one or more high-level embroidery plans, including an order of Manufacturable Components to embroider, a fill type, an entry and exit points for each Manufacturable Components, and a plurality of stitch layers.

In step 810, the Global Decisions Module interacts with the preprocessor module 802 and the Local Decisions Module 812 to coordinate the design process to determine whether the plans need to be refined.

In step 812, the Local Decisions Module refines the high-level embroidery plans into detailed stitch instructions of an embroidery stitch plan. The Local Decisions Module may generate, for example, detailed stitch instructions by determining stitch directions, stitch density, and modifications to entry and exit points for each Manufacturable Component and layer. The Local Decisions Module interacts with the Global Decisions Module and the trainer module to ensure the accuracy and quality of the stitch plans.

The subsequent steps are described in FIG. 8B.

FIG. 8B is a flow chart depicting an example process for generating embroidery stitch instructions using AI-based embroidery system. In FIG. 8B, in step 822, the visualizer module renders the embroidery-friendly design and high-level decisions as a diagram for a review. The visualizer module generates human-friendly visualizations of the final embroidery renderings of stitch plans. The visualizer module also interacts with the Verifier and the reranker module to display the design and receive feedback.

In step 824, the reranker module generates a list of variations of the embroidery stitch plan and scores and reorders the list of variations of the embroidery stitch plan based on predefined criteria. The reranker module filters out plans that do not meet a minimum threshold. The reranker module interacts with the visualizer module, the Verifier, and the Digitizer to optimize the design. The Verifier views the sorted embroidery renderings and selects their desired one. If the Verifier does not like any, the system restarts from the Global Decisions Module to make additional plan variations.

In step 826, the embroidery machine manufactures a physical embroidery based on, at least in part, the preferred embroidery stitch plan. The manufacturing Inspector reviews the quality of the embroidery and notes any issues. If there are issues, the plan goes back to the Digitizer for corrections. The manufacturing Inspector interacts with the Digitizer and the trainer module to ensure the design meets quality standards.

In step 832, the trainer module collects inputs, outputs, and feedback on the physical embroidery from various sources. The trainer module updates the preprocessor module 802, the Global Decisions Module, and the Local Decisions Module based on the inputs, the outputs, and the feedback to improve future renderings of the physical embroidery. The trainer module interacts with the training examples database to store and retrieve training examples, fine-tuning the system over time.

### 12.0. PROCESS FOR REFINING EMBROIDERY DESIGNS USING AN AI-DRIVED EMBROIDERY SYSTEM

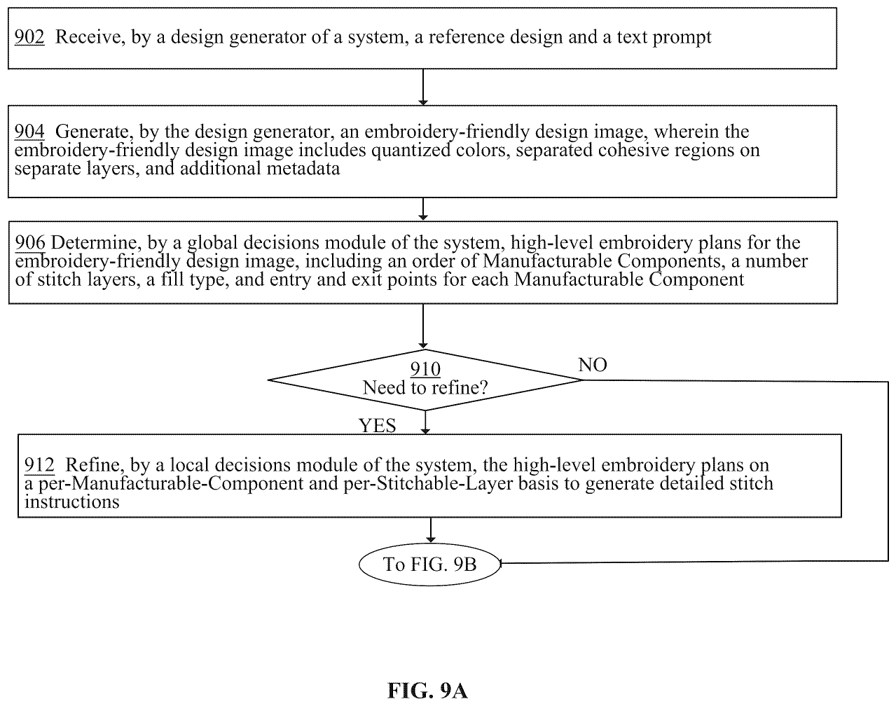

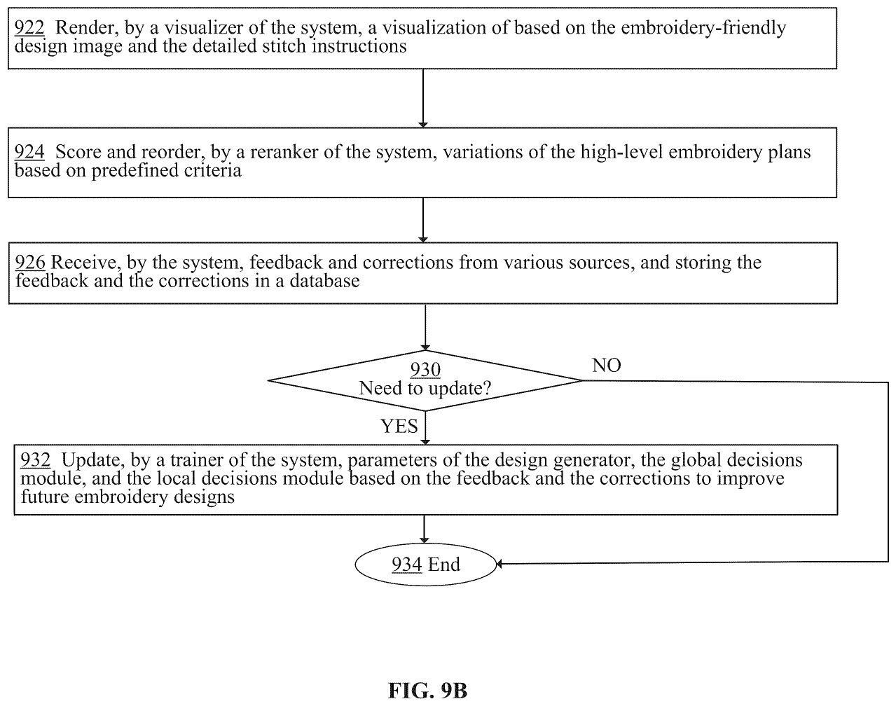

FIG. 9A is a flow chart depicting an example process for generating and refining embroidery designs using AI-based embroidery system. In FIG. 9A, the system comprises a design generator, a Global Decisions Module, and a Local Decisions Module. The system also includes a visualizer, a reranker, and a trainer. The system facilitates the generation and refinement of embroidery designs through various interconnected modules.

In step 902, a design generator receives a reference design and a text prompt from a Verifier. The design generator generates an embroidery-friendly design image, wherein the design image includes quantized colors, separated cohesive regions on separate layers, and additional metadata. The design generator processes the input data to create a design that is suitable for embroidery. The design generator uses various models to convert the input data into a layered vector format, ensuring that the output design matches the input conditions and is “embroiderable.” The design generator may use a diffusion model for generating the embroidery-friendly design image. The design generator quantizes colors in the design image using k-means clustering. The design generator separates cohesive regions in the design image using image segmentation algorithms. The additional metadata generated by the design generator includes predicted semantics of each region in the design image.

In step 904, the Global Decisions Module receives the embroidery-friendly design image and context information. The context information includes the size of the final embroidery, the substrate type, the product type, the design title, tags, the manufacturer, and the Digitizer. The Global Decisions Module determines high-level embroidery plans for the design image, including the order of Manufacturable Components, the number of stitch layers, the fill type, and the entry and exit points for each Manufacturable Component. The Global Decisions Module uses a discrete sequence prediction model to determine the high-level embroidery plans. The Global Decisions Module selects the order of Manufacturable Components for embroidery based on minimizing thread changes. The Global Decisions Module interacts with the design generator and the Local Decisions Module to coordinate the design process.

In step 906, the Local Decisions Module refines the high-level embroidery plans on a per-Manufacturable-Component and per-Stitchable-Layer basis to generate detailed stitch instructions. The Local Decisions Module receives one Manufacturable Component in the design, the stitch layer number, the suggested entry and exit points for this Manufacturable Component, the preprocessed design, the context, the digitized pattern thus far, and optional reference digitization and reference context for this Manufacturable Component. The Local Decisions Module generates detailed stitch instructions by determining stitch directions, entry and exit points, fill style, and stitch density for each Manufacturable Component and layer. The Local Decisions Module uses a hierarchical model to refine the high-level embroidery plans on a layer-by-layer basis. The Local Decisions Module interacts with the Global Decisions Module and the trainer to ensure the accuracy and quality of the stitch plans.

The process continues in FIG. 9B.

FIG. 9B is a flow chart depicting an example process for generating and refining embroidery designs using AI-based embroidery system. In FIG. 9B, in step 922, the visualizer of the system renders the embroidery-friendly design image and high-level decisions as human-friendly visualizations. The visualizer generates a visualization based on the embroidery-friendly design image and the detailed stitch instructions. The visualizer interacts with the Verifier and the reranker to display the design and receive feedback.

In step 924, the reranker of the system scores and reorders variations of the embroidery stitch plans based on predefined criteria. The reranker filters out plans that do not meet a minimum threshold. The reranker generates a list of variations of the embroidery stitch plan, and scores and reorders the list of variations based on predefined criteria. The reranker interacts with the visualizer, the Verifier, and the Digitizer to optimize the design.

In step 926, the system receives feedback and corrections from various sources, including the Verifier, the digitization expert, and the manufacturing Inspector. The feedback and corrections are stored in a database.

In step 930, the system determines whether the parameters of the design generated, etc., need to be updated. If they need to be updated, then the system performs step 932. Otherwise, the system ends the processing in step 934.

In step 932, the trainer of the system collects inputs, outputs, and human feedback from the Verifier, the digitization expert, and the manufacturing Inspector. The trainer fine-tunes the design generator, the Global Decisions Module, and the Local Decisions Module based on the collected data. The trainer updates the parameters of the design generator, the Global Decisions Module, and the Local Decisions Module based on the feedback and corrections to improve future embroidery designs. The trainer interacts with the database to store and retrieve training examples.

Once the updating is completed, and/or there was no need to update the parameters, etc., the system ends the processing in step 934.

### 13. COLOR QUANTIZATION AND CLUSTERING

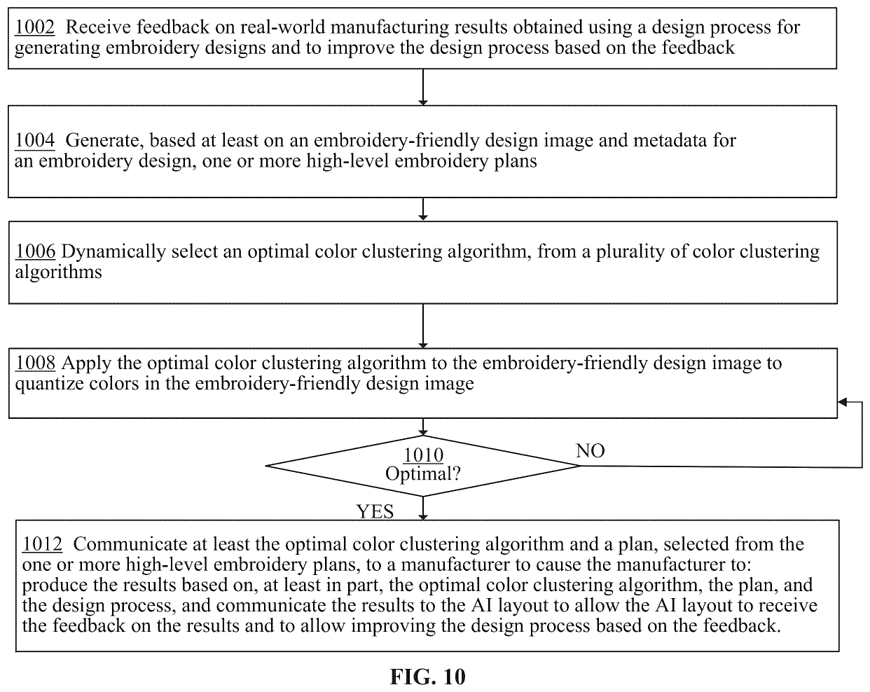

FIG. 10 is a flow chart depicting an example process for color quantization and clustering. In FIG. 10A, the system receives feedback on real world manufacturing results obtained using a design process for generating embroidery designs and to improve the design process based on the feedback.

In step 1004, the system generates, based at least on an embroidery-friendly design image and metadata for an embroidery design, one or more high-level embroidery.

In step 1006, the system dynamically selects an optimal color-clustering algorithm, from a plurality of color clustering algorithms.

In step 1008, the system applies the optimal color-clustering algorithm to the embroidery-friendly design image to quantize colors in the embroidery-friendly design image.

In step 1010, the system checks if the color-clustering algorithm is indeed optimal. If it is, then the system performs step 1012. Otherwise, the system repeats the step 1008.

In step 1012, the system communicates at least the optimal color clustering algorithm and a plan, selected from the one or more high-level embroidery plans, to a manufacturer to cause the manufacturer to: produce the results based on, at least in part, the optimal color clustering algorithm, the plan, and the design process, and communicate the results to the AI layout to allow the AI layout to receive the feedback on the results and to allow improving the design process based on the feedback.

### 14.0. IMPLEMENTATIONS MECHANISMS

Although the flow diagrams of the present application depict a particular set of steps in a specific order, other implementations may use fewer or more steps in the same or different order than those depicted in the figures.

According to one embodiment, the techniques described herein are implemented by one or more special-purpose computing devices. The special-purpose computing devices may be hard-wired to perform the techniques or may include digital electronic devices such as one or more application-specific integrated circuits (ASICs) or field programmable gate arrays (FPGAs) that are persistently programmed to perform the techniques or may include one or more general purpose hardware processors programmed to perform the techniques pursuant to program instructions in firmware, memory, other storage, or a combination. Such special-purpose computing devices may also combine custom hard-wired logic, ASICs, or FPGAs with custom programming to accomplish the techniques. The special-purpose computing devices may be desktop computer systems, portable computer systems, handheld devices, networking devices, or any other device that incorporates hard-wired and program logic to implement the techniques.

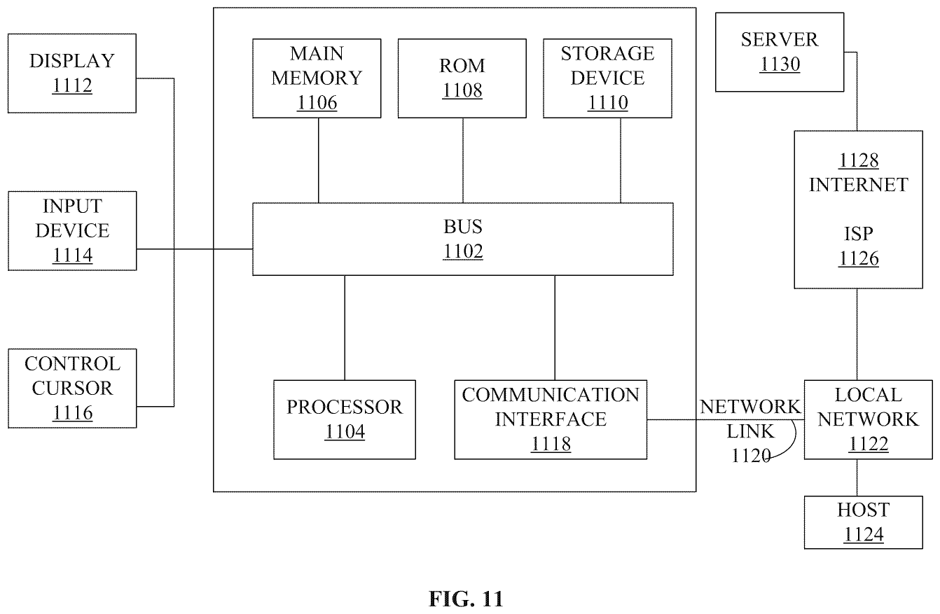

FIG. 11 is a block diagram that depicts an example computer system 1100 upon which embodiments may be implemented. Computer system 1100 includes a bus 1102 or other communication mechanism for communicating information and a processor 1104 coupled with bus 1102 for processing information. Computer system 1100 also includes a main memory 1106, such as a random-access memory (RAM) or other dynamic storage device, coupled to bus 1102 for storing information and instructions to be executed by processor 1104. Main memory 1106 may also be used to store temporary variables or other intermediate information during the execution of instructions to be executed by processor 1104. Computer system 1100 includes a read only memory (ROM) 1108 or other static storage device coupled to bus 1102 for storing static information and instructions for processor 1104. A storage device 1110, such as a magnetic or optical disk, is provided and coupled to bus 1102 to store information and instructions.

Computer system 1100 may be coupled via bus 1102 to a display 1112, such as a cathode ray tube (CRT), for displaying information to a computer user. Although bus 1102 is illustrated as a single bus, bus 1102 may comprise one or more buses. For example, bus 1102 may include without limitation a control bus by which processor 1104 controls other devices within computer system 1100, an address bus by which processor 1104 specifies memory locations of instructions for execution or any other type of bus for transferring data or signals between components or modules of computer system 1100.

In some implementations, an input device 1114, including alphanumeric and other keys, is coupled to bus 1102 for communicating information and command selections to processor 1104. Another type of user input device is cursor control 1116, such as a mouse, a trackball, or cursor direction keys for communicating direction information and command selections to processor 1104 and controlling cursor movement on display 1112. This input device typically has two degrees of freedom in two axes, a first axis (e.g., x) and a second axis (e.g., y), that allows the device to specify positions in a plane. In some other implementations, the input to the present system may be provided in the form of voice input, image input, and/or camera-based input. In fact, certain system components, such as the Verifier, may not have to rely on inputs from a keyboard, a mouse, or other physical interface. Instead, they may depend on the voice, image, or similar inputs.

Computer system 1100 may implement the techniques described herein using customized hard-wired logic, one or more ASICs or FPGAs, firmware and program logic or computer software which, in combination with the computer system, causes or programs computer system 1100 to be a special-purpose machine. According to one embodiment, those techniques are performed by computer system 1100 in response to processor 1104 executing one or more sequences of one or more instructions contained in main memory 1106. Such instructions may be read into main memory 1106 from another computer-readable medium, such as storage device 1110. Execution of the sequences of instructions contained in main memory 1106 causes processor 1104 to perform the process steps described herein. In alternative embodiments, hard-wired circuitry may be used in place of or in combination with software instructions to implement the embodiments. Thus, embodiments are not limited to any specific combination of hardware circuitry and software.

The term “computer-readable medium” refers to any medium that provides data that causes a computer to operate in a specific manner. In an embodiment implemented using computer system 1100, various computer-readable media are involved, for example, in providing instructions to processor 1104 for execution. Such a medium may take many forms, including, but not limited to, non-volatile media and volatile media. Non-volatile media includes, for example, optical or magnetic disks, such as storage device 1110. Volatile media includes dynamic memory, such as main memory 1106. Typical forms of computer-readable media include, for example, a floppy disk, a flexible disk, hard disk, magnetic tape, or any other magnetic medium, a CD-ROM, any other optical medium, a RAM, a PROM, and EPROM, a FLASH-EPROM, any other memory chip, or memory cartridge, or any other medium from which a computer can read.

Various forms of computer-readable media may be involved in carrying one or more sequences of one or more instructions to processor 1104 for execution. For example, the instructions may initially be carried on a magnetic disk of a remote computer. The remote computer can load the instructions into its dynamic memory and send them over a telephone line using a modem. A modem local to computer system 1100 can receive the data on the telephone line and use an infrared transmitter to convert the data to an infrared signal. An infra-red detector can receive the data in the infra-red signal, and appropriate circuitry can place the data on bus 1102. Bus 1102 carries the data to main memory 1106, from which processor 1104 retrieves and executes the instructions. The instructions received by main memory 1106 may optionally be stored on storage device 1110 before or after execution by processor 1104.

Computer system 1100 also includes a communication interface 1118 coupled to bus 1102. Communication interface 1118 provides a two-way data communication coupling to a network link 1120 connected to a local network 1122. For example, communication interface 1118 may be an integrated service digital network (ISDN) card or a modem to connect data to a corresponding telephone line. Another example is Communication Interface 1118, a local area network (LAN) card that provides a data communication connection to a compatible LAN. Wireless links may also be implemented. In any such implementation, communication interface 1118 sends and receives electrical, electromagnetic, or optical signals that carry digital data streams representing various types of information.

Network link 1120 typically provides data communication to other data devices through one or more networks. For example, network link 1120 may connect through local network 1122 to a host computer 1124 or data equipment operated by an Internet Service Provider (ISP) 1126. ISP 1126 provides data communication services through the worldwide packet data communication network, now called the “Internet” 1128. Local network 1122 and Internet 1128 both use electrical, electromagnetic, or optical signals that carry digital data streams.

Computer system 1100 can send messages and receive data, including program code, through the network(s), network link 1120, and communication interface 1118. In the Internet example, server 1130 might transmit a requested code for an application program through Internet 1128, ISP 1126, local network 1122, and communication interface 1118. The received code may be executed by processor 1104 as it is received and stored in storage device 1110 or other non-volatile storage for later execution.

In the foregoing specification, embodiments have been described with reference to numerous specific details that may vary from implementation to implementation. Thus, the sole and exclusive indicator of what is, and is intended by the applicants to be, the approach is the set of claims issued from this application in the specific form in which such claims are issued, including any subsequent correction. Hence, no limitation, element, property, feature, advantage, or attribute that is not expressly recited in a claim should limit the scope of such claim in any way. Accordingly, the specification and drawings are to be regarded in an illustrative rather than a restrictive sense.

What is claimed is:

1. A computer-implemented method for generating embroidery stitch instructions, the method comprising:
receiving, by a preprocessor module of a system, an input prompt comprising at least one of a text prompt, an image, or a selection input;
generating, by the preprocessor module, an embroidery-friendly design based on the input prompt, wherein the embroidery-friendly design comprises quantized colors, cohesive regions on separate layers, and additional metadata;
receiving, by a global decisions module of the system, the embroidery-friendly design and context information, wherein the context information includes at least one of: a size of a final embroidery, a substrate type, a product type, a design title, tags, a manufacturer, and a digitizer;
generating, by the global decisions module, one or more high-level embroidery plans, including an order of Manufacturable Components to embroider, a fill type, an entry and exit points for each Manufacturable Component, and a plurality of Stitch Layers;
refining, by a local decisions module of the system, the one or more high-level embroidery plans into detailed stitch instructions of an embroidery stitch plan, including stitch directions, stitch density, and modifications to entry and exit points for each Manufacturable Component and layer;
rendering, by a visualizer module of the system, the embroidery-friendly design and high-level decisions as a diagram for a review;
generating a list of variations of the embroidery stitch plan, and scoring and reordering, by a reranker module of the system, the list of variations of the embroidery stitch plan based on predefined criteria;
receiving a selection of a preferred embroidery stitch plan from the list of variations of the embroidery stitch plan;
manufacturing, by an embroidery machine, a physical embroidery based on, at least in part, the preferred embroidery stitch plan;
collecting, by a trainer module of the system, inputs, outputs, and feedback on the physical embroidery from various sources;
updating, by the trainer module, the preprocessor module, the global decisions module, and the local decisions module based on the inputs, the outputs, and the feedback to improve future renderings of the physical embroidery.

2. The method of claim 1, further comprising:
dynamically selecting, by a design generator, an optimal color clustering algorithm for quantizing colors from a set of: hierarchical clustering, k-means clustering, octree clustering, or adaptive clustering;
optimizing the optimal color clustering algorithm to produce an embroidery-friendly design image, maximize available resources, and minimize an overall number of turns;
wherein the optimal color clustering algorithm is dynamically selected based on one or more of:
input parameters such as a number of available thread colors, a level of artwork detail, a size of a final embroidered piece, or fabric color and type;
system parameters including available computational resources; or
optimization goals including minimization of a number of turns to achieve a final design;
wherein the design generator utilizes machine learning techniques to continuously improve the selection of the optimal color clustering algorithm based on historical data of customer interactions and design outcomes.

3. The method of claim 2, further comprising:
processing multiple types of inputs simultaneously, including text prompts and reference images refining the inputs based on the feedback,
allowing iterative improvements to the physical embroidery.

4. The method of claim 1, further comprising using discrete sequence prediction models to generate the one or more high-level embroidery plans.

5. The method of claim 4, further comprising incorporating context-specific information such as a substrate type, a product type, and a design size to tailor the one or more high-level embroidery plans.

6. The method of claim 1, further comprising using hierarchical diffusion models to generate detailed stitch instructions layer-by-layer.

7. The method of claim 6, further comprising using entry and exit points, stitch directions, and stitch density based on the one or more high-level embroidery plans received from the global decisions module.

8. The method of claim 1, further comprising using advanced rendering techniques to create realistic simulations of the physical embroidery.

9. The method of claim 8, further comprising ensuring that the preferred embroidery stitch plan matches the physical embroidery by simulating one or more physical properties of stitches and substrate of the preferred embroidery stitch plan.

10. A non-transitory computer-readable storage media storing one or more computer instructions which, when executed by one or more computer processors, cause the one or more computer processors to perform:
receiving, by a preprocessor module of a system, an input prompt comprising at least one of a text prompt, an image, or a selection input;
generating, by the preprocessor module, an embroidery-friendly design based on the input prompt, wherein the embroidery-friendly design comprises quantized colors, cohesive regions on separate layers, and additional metadata;
receiving, by a global decisions module of the system, the embroidery-friendly design and context information, wherein the context information includes at least one of: a size of a final embroidery, a substrate type, a product type, a design title, tags, a manufacturer, and a digitizer;
generating, by the global decisions module, one or more high-level embroidery plans, including an order of Manufacturable Components to embroider, a fill type, an entry and exit points for each Manufacturable Component, and a plurality of Stitch Layers;
refining, by a local decisions module of the system, the one or more high-level embroidery plans into detailed stitch instructions of an embroidery stitch plan, including stitch directions, stitch density, and modifications to entry and exit points for each Manufacturable Component and layer;
rendering, by a visualizer module of the system, the embroidery-friendly design and high-level decisions as a diagram for a review;
generating a list of variations of the embroidery stitch plan, and scoring and reordering, by a reranker module of the system, the list of variations of the embroidery stitch plan based on predefined criteria;
receiving a selection of a preferred embroidery stitch plan from the list of variations of the embroidery stitch plan;
manufacturing, by an embroidery machine, a physical embroidery based on, at least in part, the preferred embroidery stitch plan;
collecting, by a trainer module of the system, inputs, outputs, and feedback on the physical embroidery from various sources;
updating, by the trainer module, the preprocessor module, the global decisions module, and the local decisions module based on the inputs, the outputs, and the feedback to improve future renderings of the physical embroidery.

11. An apparatus for generating embroidery stitch instructions, the apparatus comprising:
a design generator configured to receive input data including at least one of a text prompt, a reference image, or a combination thereof, and to generate an embroidery-friendly design image with quantized colors, cohesive regions on separate layers, and additional metadata;
a global decisions module configured to receive the embroidery-friendly design image and metadata, and to generate one or more high-level embroidery plans including an order of Manufacturable Components, one or more Stitch Layers, a fill type, and entry and exit points for each Manufacturable Component;
a local decisions module configured to receive the one or more high-level embroidery plans and to generate detailed stitch instructions for each Manufacturable Component and layer, including stitch directions, stitch density, and modifications to entry and exit points;
a visualizer configured to render multiple variations of the detailed stitch instructions and embroidery designs for review;
a reranker configured to score and filter the variations of the detailed stitch instructions based on predefined criteria;
a trainer configured to collect inputs, outputs, and feedbacks from various stages, and to fine-tune the design generator, global decisions module, and local decisions module based on the inputs, the outputs, and the feedbacks.

12. The apparatus of claim 11, wherein the design generator further performs:
dynamically selecting an optimal color clustering algorithm for quantizing colors from a set of: hierarchical clustering, k-means clustering, octree clustering, or adaptive clustering;
optimizing the optimal color clustering algorithm to produce an embroidery-friendly design image, maximize available resources, and minimize an overall number of turns;
wherein the optimal color clustering algorithm is dynamically selected based on one or more of:
input parameters such as a number of available thread colors, a level of artwork detail, a size of a final embroidered piece, or fabric color and type;
system parameters including available computational resources; or
optimization goals including minimization of a number of turns to achieve a final design;
wherein the design generator utilizes machine learning techniques to continuously improve the selection of the optimal color clustering algorithm based on historical data of customer interactions and design outcomes.

13. The apparatus of claim 12, wherein the design generator is further configured to simultaneously process multiple types of inputs, including text prompts and reference images;
wherein the design generator refines the inputs based on a user feedback, allowing iterative improvements to the one or more high-level embroidery plans.

14. The apparatus of claim 11, wherein the global decisions module uses discrete sequence prediction models to generate the one or more high-level embroidery plans.

15. The apparatus of claim 14, wherein the global decisions module incorporates context-specific information such as a substrate type, a product type, and a design size to tailor the one or more high-level embroidery plans.

16. The apparatus of claim 11, wherein the local decisions module uses hierarchical diffusion models to generate detailed stitch instructions layer-by-layer.

17. The apparatus of claim 16, wherein the local decisions module refines entry and exit points, stitch directions, and stitch density based on the one or more high-level embroidery plans received from the global decisions module.

18. The apparatus of claim 11, wherein the visualizer uses advanced rendering techniques to create realistic simulations of a physical embroidery.

19. The apparatus of claim 18, wherein the visualizer ensures that a rendered design matches the physical embroidery by simulating one or more physical properties of stitches and substrate.
